(19) United States
(12) Patent Application Publication
(10) Pub. No.: US 2013/0203253 A1
(43) Pub. Date: Aug. 8, 2013

(54) METHOD OF FORMING PATTERN AND METHOD OF MANUFACTURING SEMICONDUCTOR DEVICE

(71) Applicants: Ai INOUE, Kanagawa (JP); Sayaka Tamaoki, Kanagawa (JP); Takashi Obara, Kanagawa (JP)

(72) Inventors: Ai INOUE, Kanagawa (JP); Sayaka Tamaoki, Kanagawa (JP); Takashi Obara, Kanagawa (JP)

(21) Appl. No.: 13/597,813

(22) Filed: Aug. 29, 2012

(30) Foreign Application Priority Data
Feb. 6, 2012 (JP) 2012-023468

(51) Int. Cl. H01L 21/302; B44C 1/22

(52) U.S. Cl. 438/689; 216/41; 257/E21.214

(57) ABSTRACT

In a method of forming a pattern according to an embodiment, a first oblique linear pattern arranged at a first oblique angle with respect to a first parallel linear pattern and a second oblique linear pattern arranged at a second oblique angle with respect to the first parallel linear pattern are formed. Then, a pattern is formed in a region in which the first oblique linear pattern overlaps the second oblique linear pattern. A second parallel linear pattern is formed using the first parallel linear pattern and the pattern such that the second parallel linear pattern is divided by the overlap region. At least one of the first and second oblique angles is an angle other than a right angle.

### CROSS-REFERENCE TO RELATED APPLICATIONS

This application is based upon and claims the benefit of priority from Japanese Patent Application No. 2012-023468, filed on Feb. 6, 2012; the entire contents of which are incorporated herein by reference.

### FIELD

Embodiments described herein relate generally to a method of forming a pattern and a method of manufacturing a semiconductor device.

### BACKGROUND

In recent years, with the size reduction of large scale integration (LSI), techniques of forming a fine semiconductor circuit pattern on a substrate have been developed. A sidewall process is known as one of techniques of forming a fine semiconductor circuit pattern on a substrate.

For example, when a plurality of linear line patterns are formed using the sidewall process, it is difficult to form line patterns such that a linear line pattern interposed between neighboring linear line patterns is divided in midstream. Further, when a plurality of linear space patterns are formed using the sidewall process, it is difficult to form space patterns such that a linear space pattern interposed between neighboring space line patterns is divided in midstream.

This is because when a columnar pattern to divide the linear line pattern or the linear space pattern in midstream is formed to be small, the columnar pattern is likely to collapse. For this reason, there is a need for a technique of forming linear patterns such that a linear pattern interposed between neighboring linear patterns is divided with a high degree of accuracy without affecting the shapes of the neighboring linear patterns.

### BRIEF DESCRIPTION OF THE DRΔWINGS

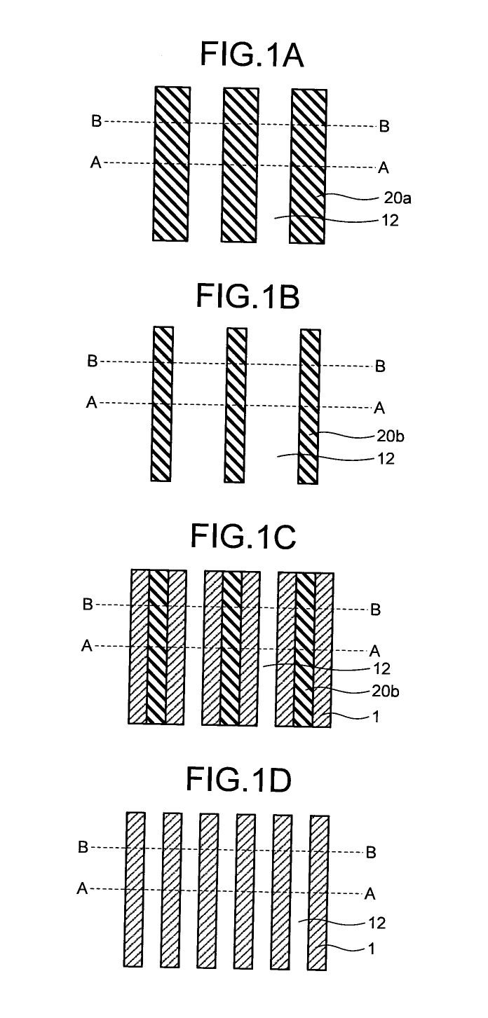

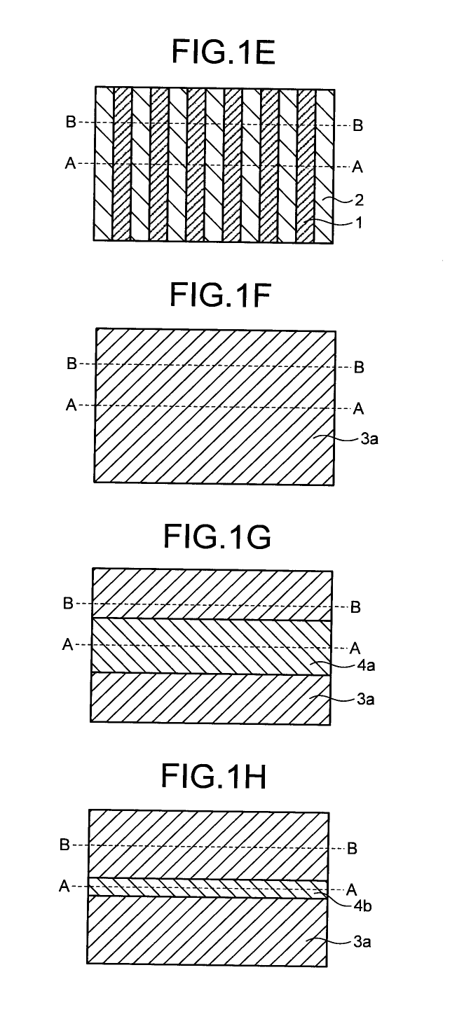

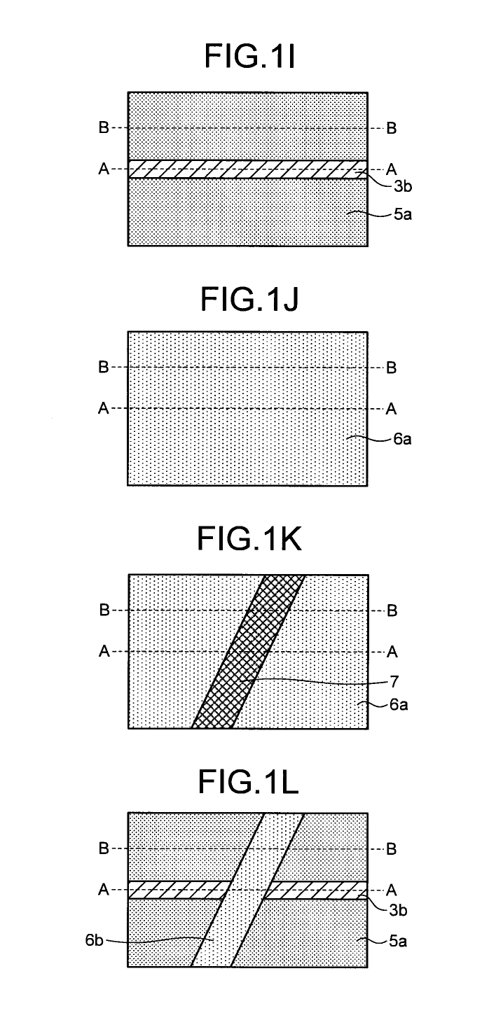

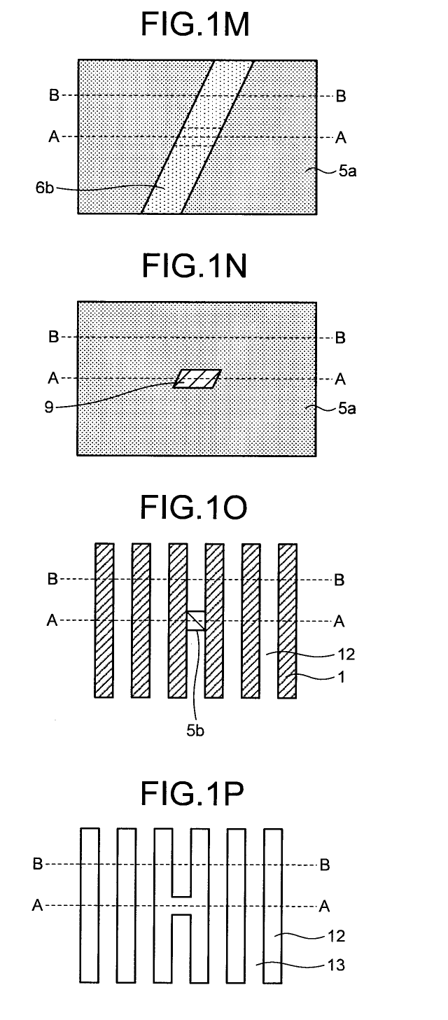

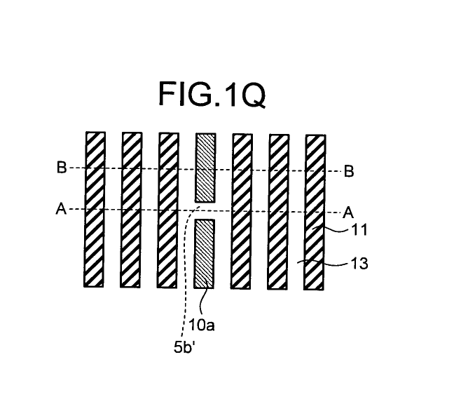

FIGS. 1A to 1Q are top views of a substrate for describing a pattern forming process according to a first embodiment;

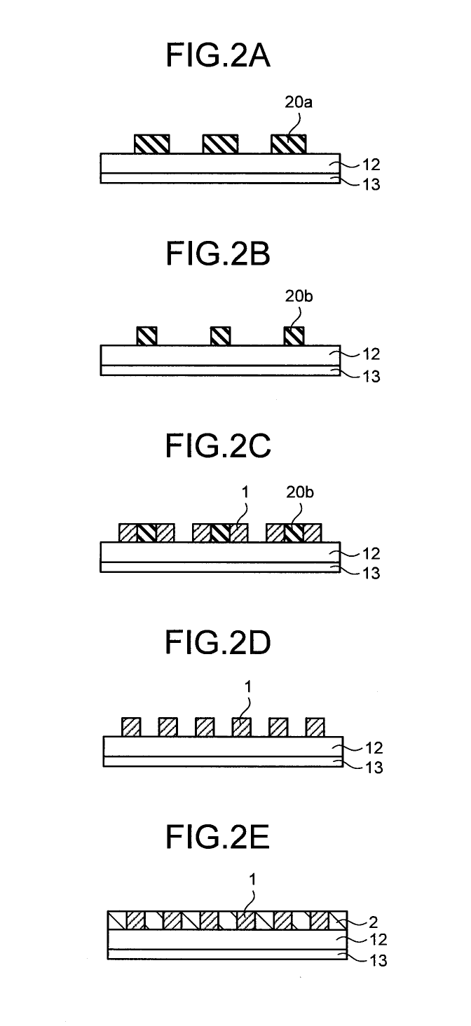

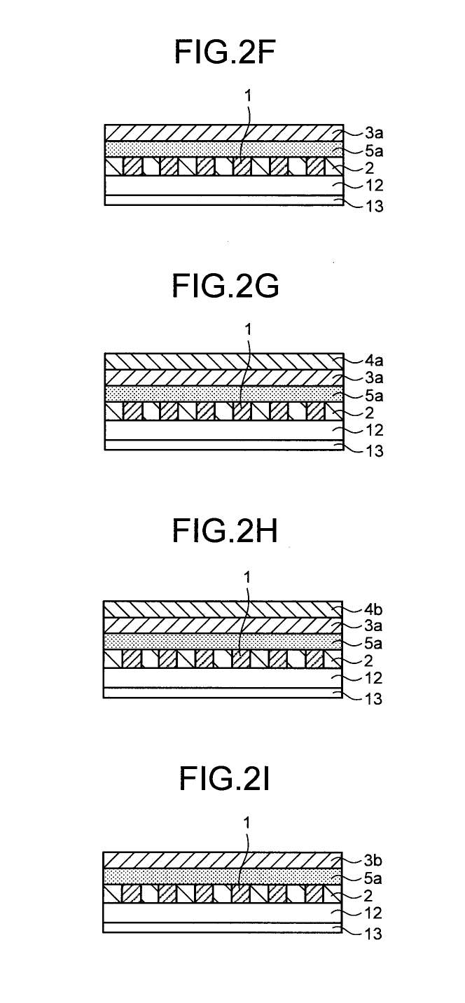

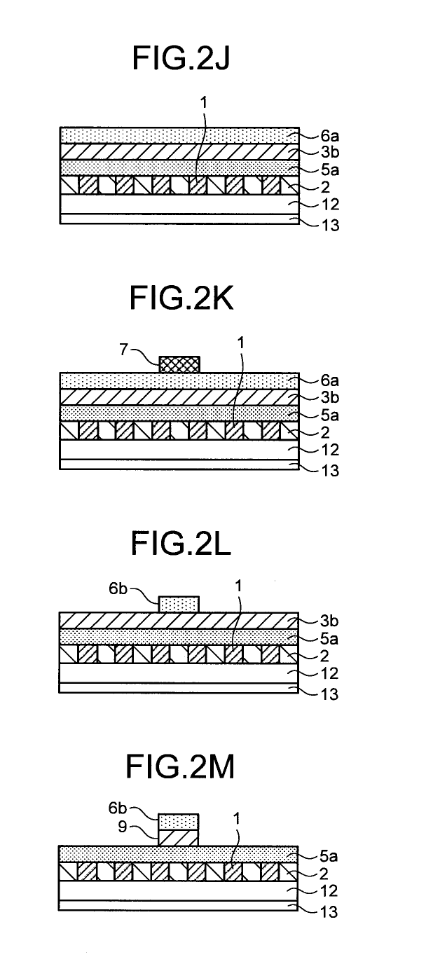

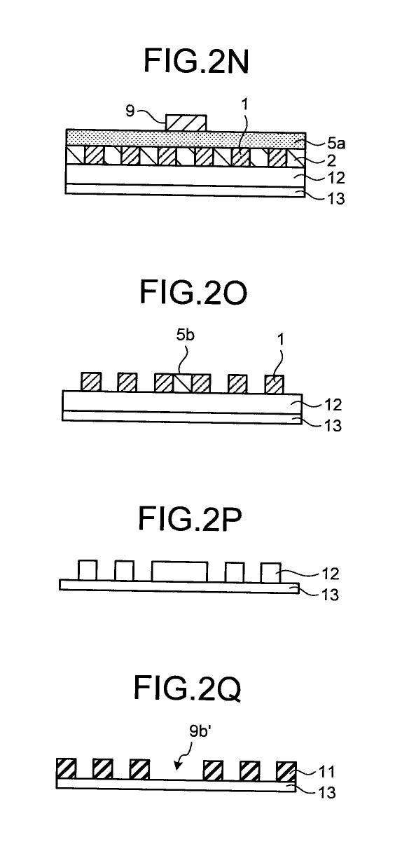

FIGS. 2A to 2Q are A-A cross-sectional views of a substrate for describing the pattern forming process according to the first embodiment;

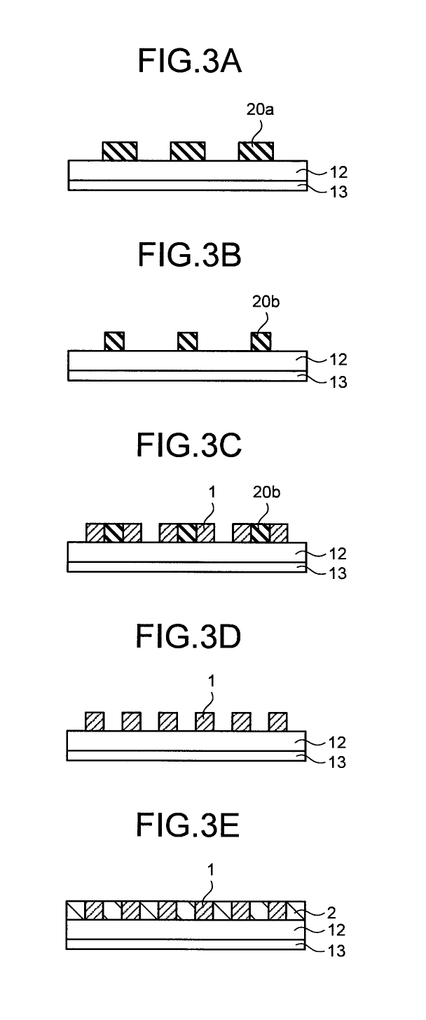

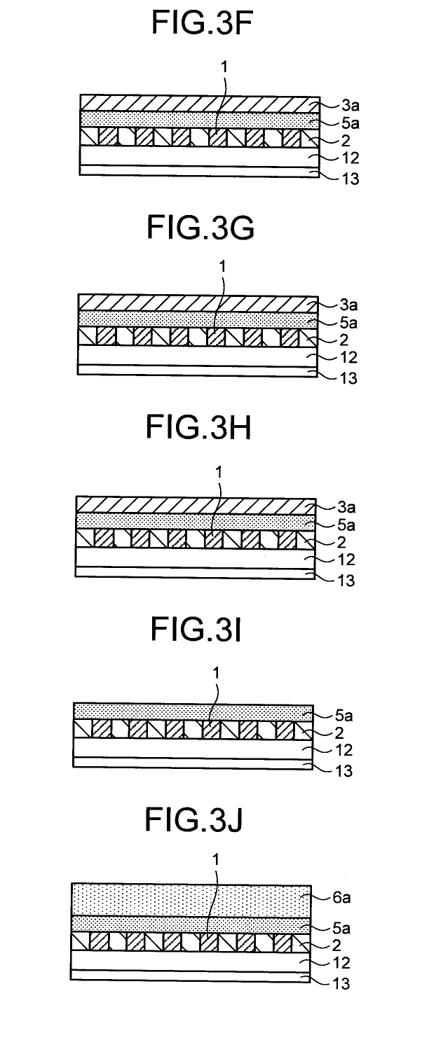

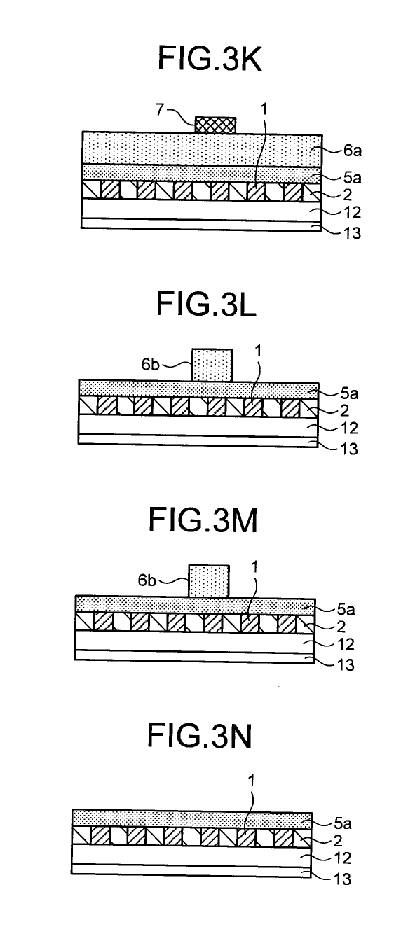

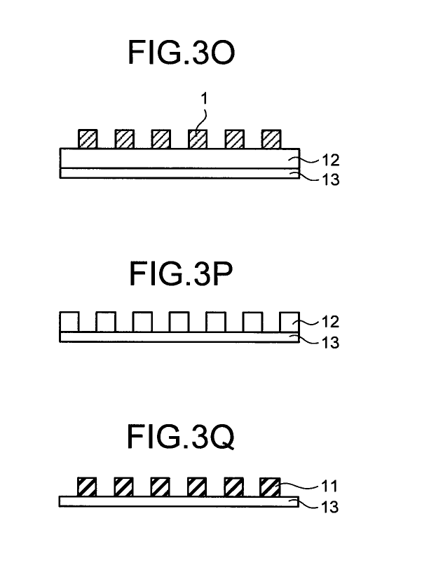

FIGS. 3A to 3Q are B-B cross-sectional views of a substrate for describing the pattern forming process according to the first embodiment;

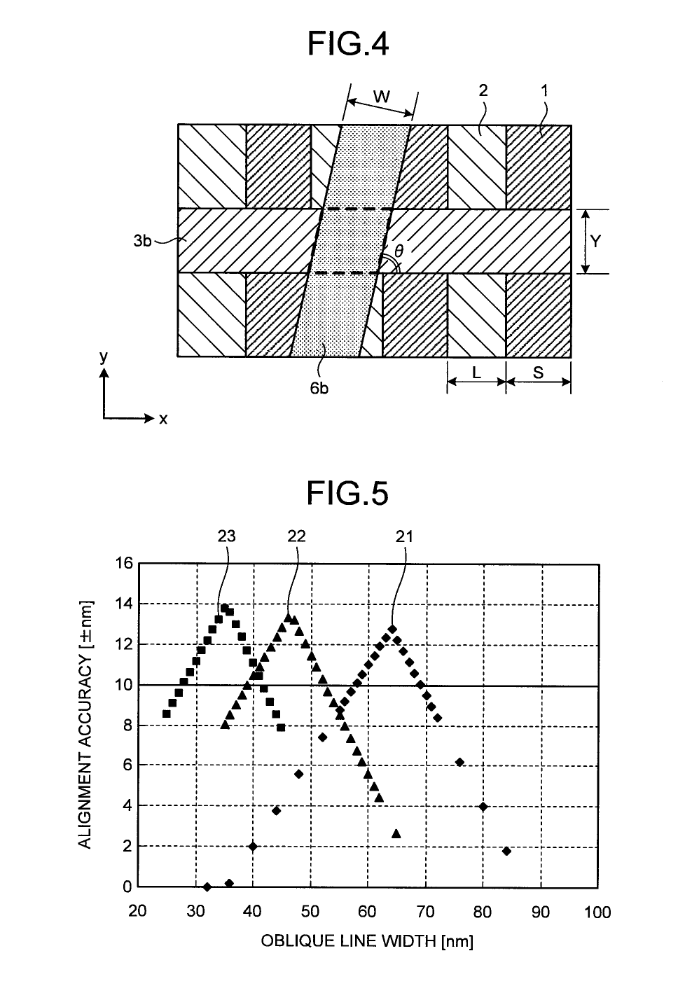

FIG. 4 is a diagram for describing an oblique angle of an oblique line pattern;

FIG. 5 is a diagram for describing a relation between an oblique line width and an alignment accuracy;

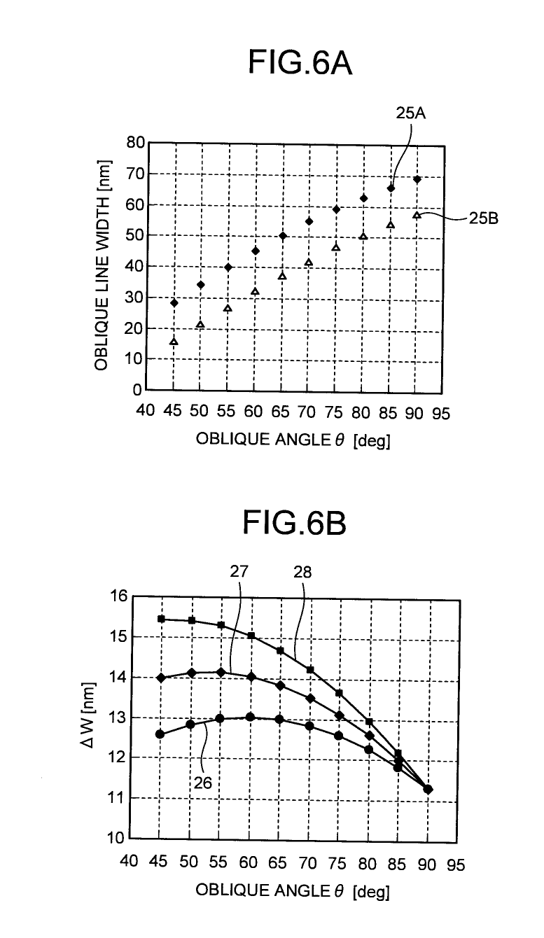

FIGS. 6A and 6B are diagrams for describing a relation between an oblique angle and an oblique line width;

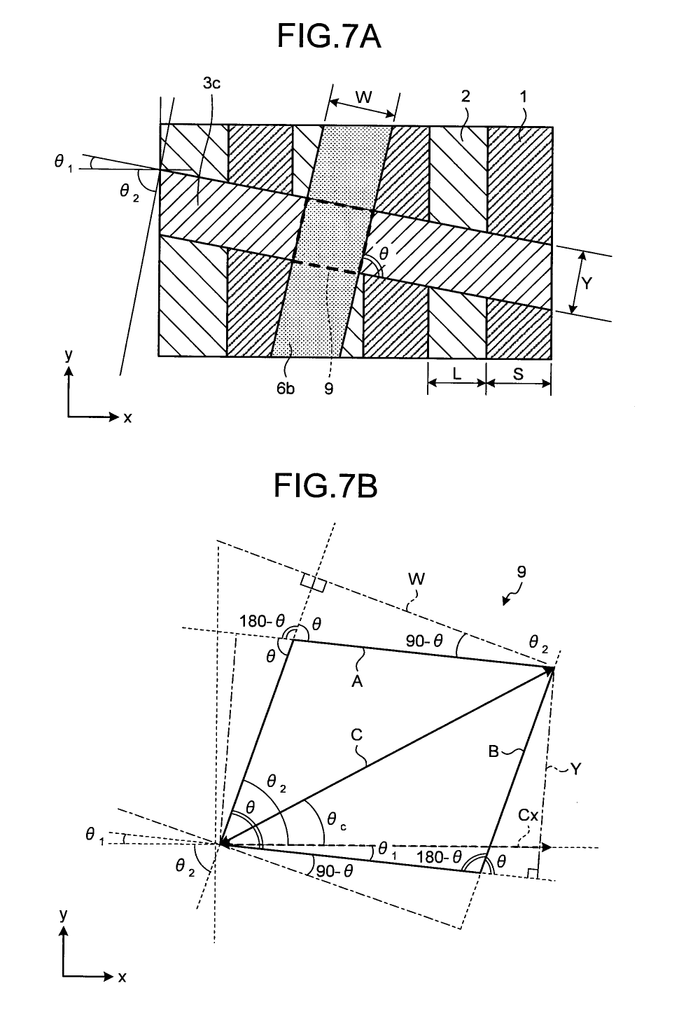

FIGS. 7A and 7B are diagrams for describing oblique angles of the first and second oblique line patterns;

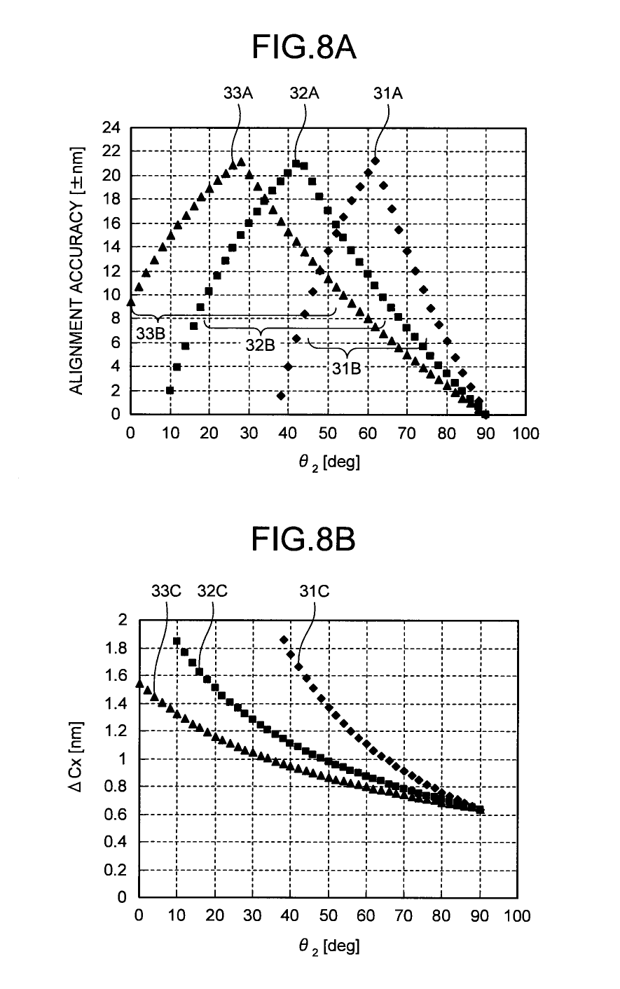

FIGS. 8A and 8B are diagrams for describing a relation between an oblique angle of the second oblique line pattern and an alignment accuracy of the second oblique line pattern;

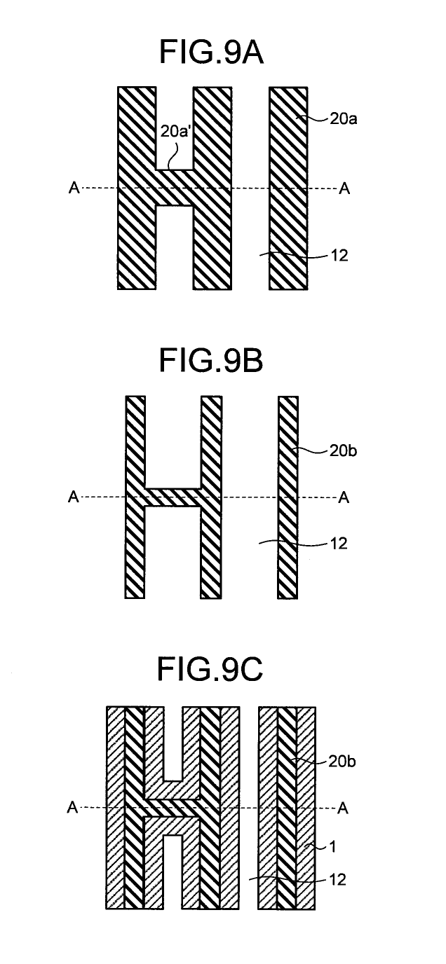

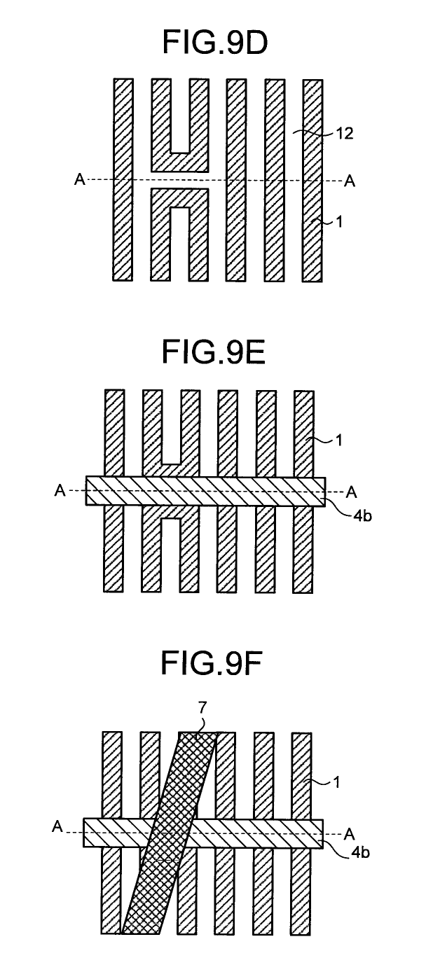

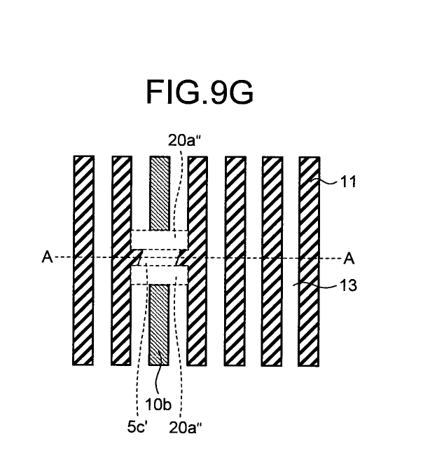

FIGS. 9A to 9G are top views of a substrate for describing a pattern forming process according to a second embodiment;

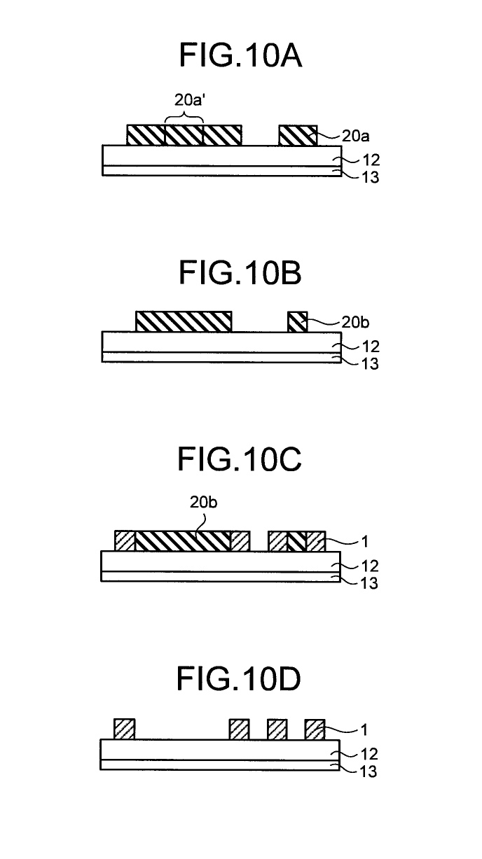

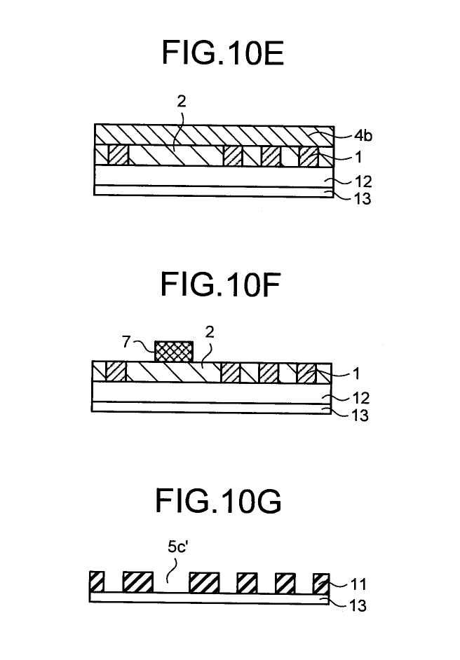

FIGS. 10A to 10G are A-A cross-sectional views of a substrate for describing the pattern forming process according to the second embodiment;

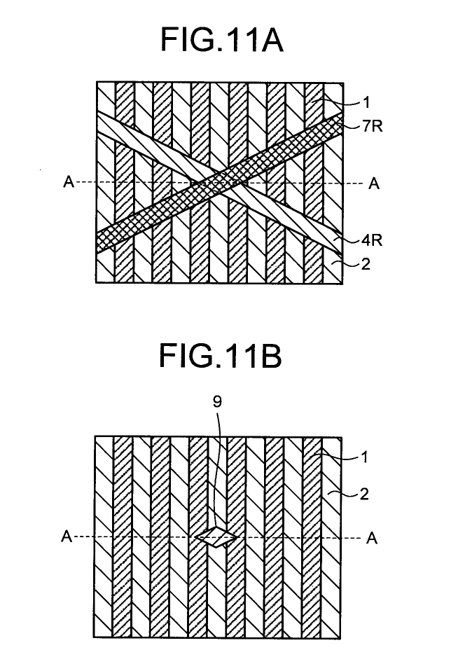

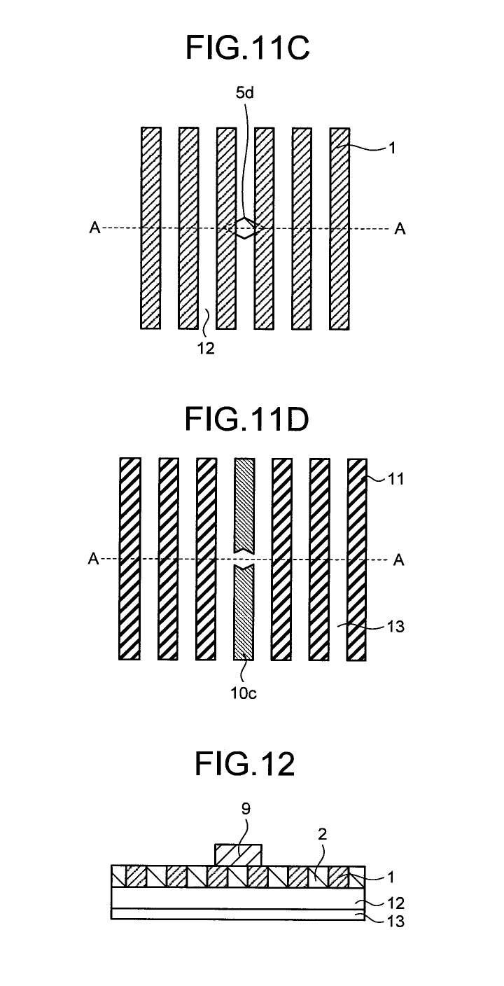

FIGS. 11A to 11D are top views of a substrate for describing a pattern forming process according to a third embodiment;

FIG. 12 is an A-A cross-sectional view of a substrate for describing the pattern forming process according to the third embodiment;

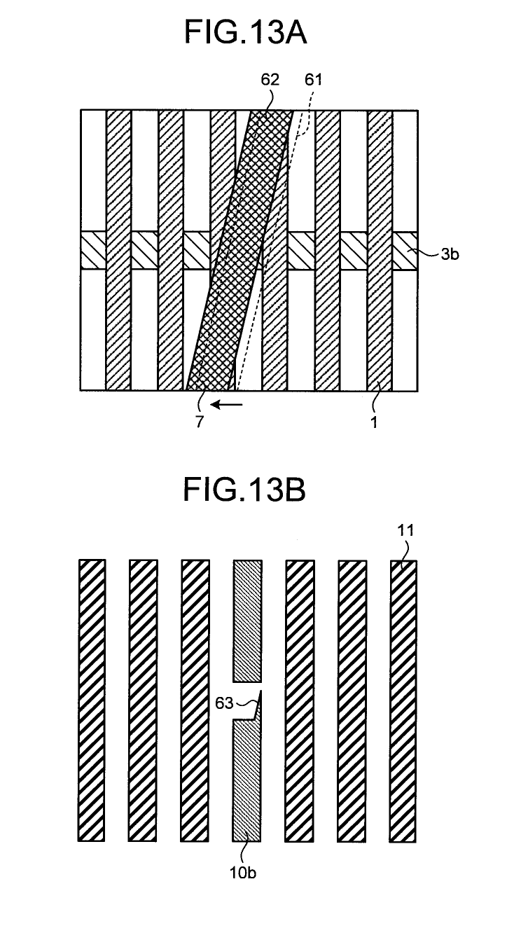

FIGS. 13A and 13B are diagrams for describing misalignment of an oblique line pattern;

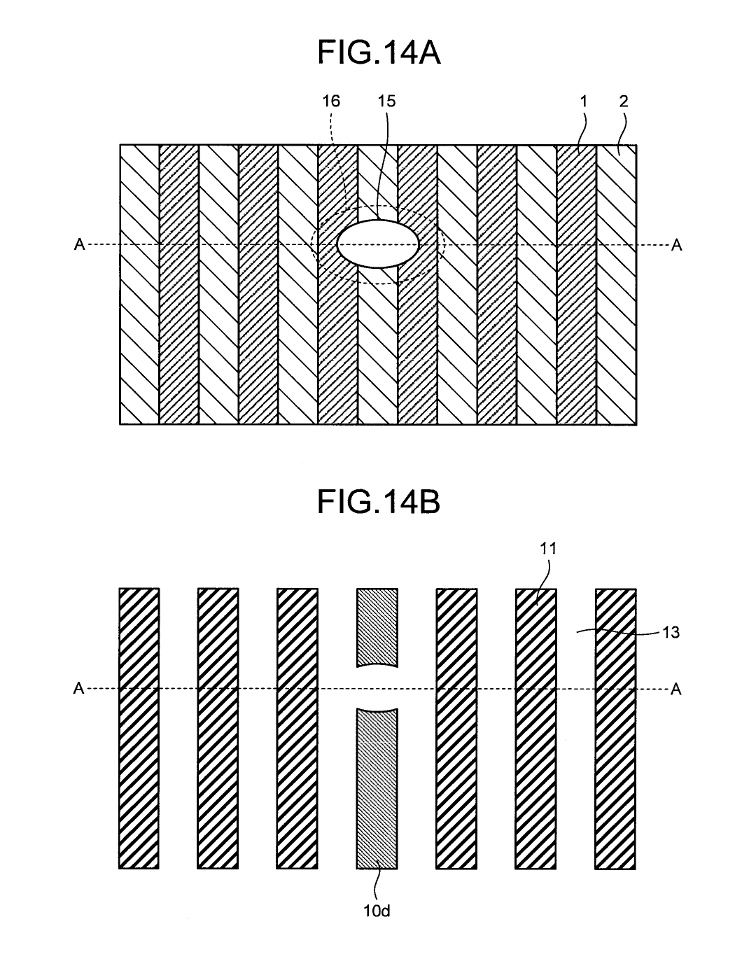

FIGS. 14A and 14B are top views of a substrate for describing a pattern forming process according to a fourth embodiment;

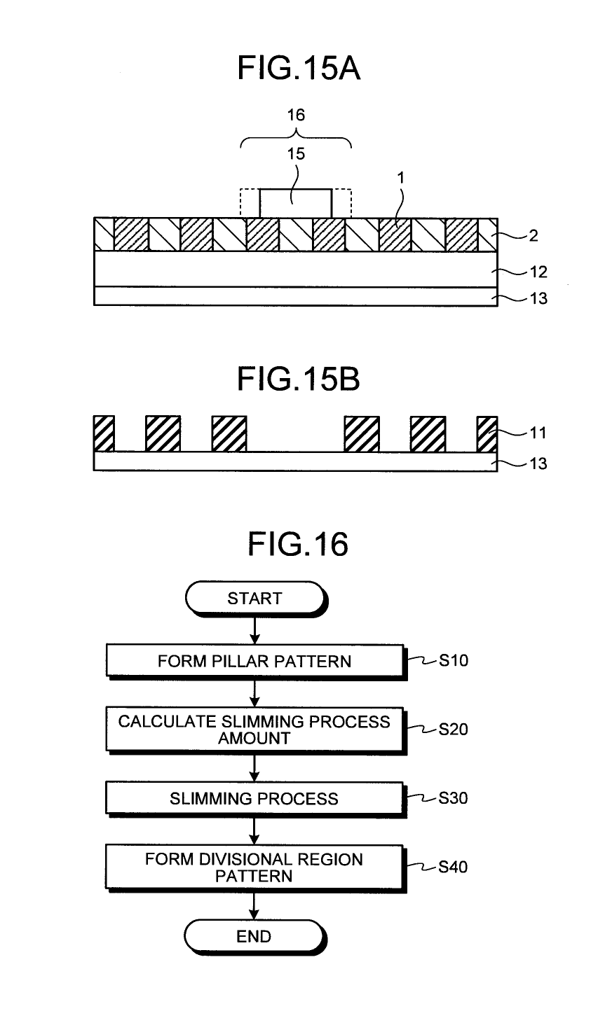

FIGS. 15A and 15B are A-A cross-sectional views of a substrate for describing the pattern forming process according to the fourth embodiment;

FIG. 16 is a flowchart illustrating the pattern forming process according to the fourth embodiment; and

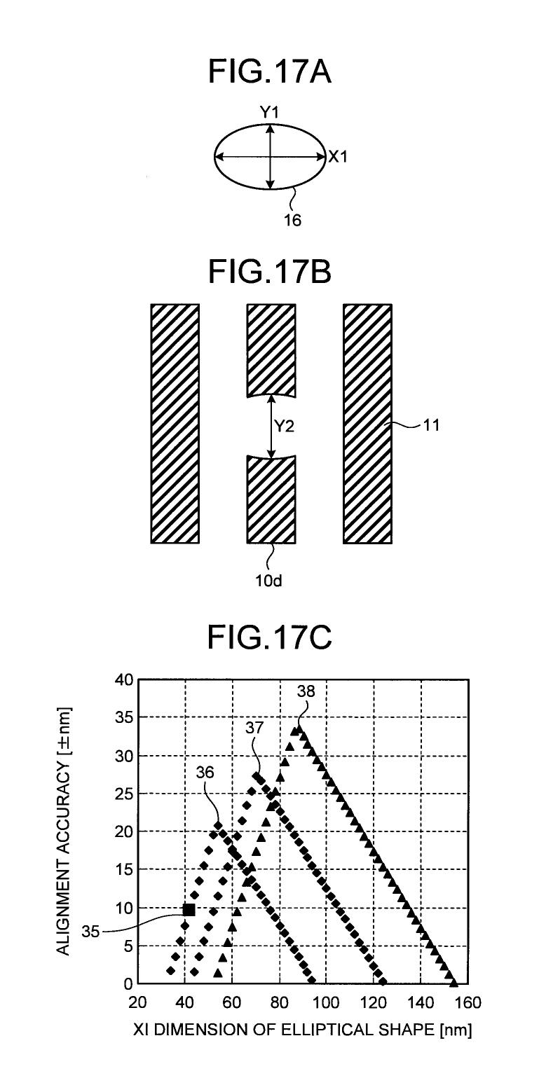

FIGS. 17A to 17C are diagrams for describing a relation between a pillar pattern dimension and an alignment accuracy.

### DETAILED DESCRIPTION

According to embodiments, a method of forming a pattern is provided. In a method of forming a pattern, a plurality of linear patterns arranged in a parallel direction are formed as a first parallel linear pattern. Then, a linear pattern arranged above the first parallel linear pattern at a first oblique angle with respect to the first parallel linear pattern is formed as a first oblique linear pattern. Then, a linear pattern that passes above a first overlap region which is one of regions in which the first parallel linear pattern overlaps the first oblique linear pattern and is arranged at a second oblique angle with respect to the first parallel linear pattern is formed as a second oblique linear pattern. Then, a pattern is formed, using the first and second oblique linear patterns, in a second overlap region in which the first oblique linear pattern overlaps the second oblique linear pattern. Then, a second parallel linear pattern is formed using the pattern such that a plurality of second parallel linear patterns which are formed using the first parallel linear pattern and arranged in a parallel direction are divided by the second overlap region, and each of the second parallel linear patterns is not divided in midstream in a region other than the second overlap region. Here, at least one of the first and second oblique angles is an angle other than a right angle.

Hereinafter, exemplary embodiment of a method of forming a pattern and a method of manufacturing a semiconductor device will be described in detail with reference to the accompanying drawings. The present invention is not limited by the following embodiments.

### First Embodiment

FIGS. 1A to 3Q are views for describing a pattern forming process according to a first embodiment. FIGS. 1A to 1Q are top views of a substrate for describing the pattern forming process according to the first embodiment. FIGS. 2A to 2Q are A-A cross-sectional views of a substrate for describing the pattern forming process according to the first embodiment. FIGS. 3A to 3Q are B-B cross-sectional views of a substrate for describing the pattern forming process according to the first embodiment. FIGS. 2A to 2Q and FIGS. 3A to 3Q correspond to FIGS. 1A to 1Q, respectively.

A processing target film 12 is formed on a substrate 13 such as a wafer. The processing target film 12 is a film used to form a desired processing pattern, and a predetermined pattern is formed on the processing target film 12 by a subsequent process. Here, the desired processing pattern refers to a line pattern such as an interconnection pattern, and refers to an interconnection pattern 11 which will be described later in the present embodiment.

The processing target film 12 is patterned into a pattern which is to be filled with the interconnection pattern 11. The interconnection pattern 11 according to the present embodiment is configured to include a pattern (hereinafter, referred to as a “divisional linear pattern”) having the shape in which a single linear pattern is divided in midstream. The interconnection pattern 11 refers to a pattern in which linear patterns are formed such that a linear pattern interposed between neighboring linear patterns is divided in midstream. In other words, the interconnection pattern 11 includes a divisional linear pattern interposed between neighboring linear patterns. An example of forming the divisional linear pattern on an A-A line (an A-A cross section) will be described with reference to FIGS. 1A to 3Q.

<FIG. 1A, FIG. 2A, and FIG. 3A>

After the processing target film 12 is formed on the substrate 13, a core pattern 20a used in the sidewall process (a double patterning technique by the sidewall process) is formed on the processing target film 12. The core pattern 20a is a linear pattern group including a plurality of linear patterns arranged in a parallel direction.

<FIG. 1B, FIG. 2B, and FIG. 3B>

Thereafter, the core pattern 20a is subjected to a slimming process, and thus a slimming pattern 20b is formed.

<FIG. 1C, FIG. 2C, and FIG. 3C>

Then, a sidewall deposition film is deposited to cover the slimming pattern 20b. Thereafter, the sidewall deposition film is etched by anisotropic etching, and thus a sidewall pattern 1 is formed from the sidewall deposition film.

<FIG. 1D, FIG. 2D, and FIG. 3D>

Then, the slimming pattern 20b is subjected to wet etching. As a result, the slimming pattern 20b is removed, and the sidewall pattern 1 remains on the processing target film 12. As described above, in the sidewall process (the sidewall line transfer process), the sidewall pattern 1 is formed on the sidewall of the core (the slimming pattern 20b), then the core is removed, and thus the sidewall pattern 1 remains on the substrate. The sidewall pattern 1 is configured with a plurality of linear patterns arranged in the parallel direction.

<FIG. 1E, FIG. 2E, and FIG. 3E>

Thereafter, a space between the sidewall patterns 1 is filled with an etching suppression material 2.

<FIG. 1F, FIG. 2F, and FIG. 3F>

Then, an upper surface of the sidewall pattern 1 and an upper surface of the etching suppression material 2 are covered with a first etching film 5a, and an upper surface of the first etching film 5a is covered with a second etching film 3a. The second etching film 3a is a film used to form the divisional linear pattern, and the line pattern is patterned by a subsequent process. A line pattern formed using the second etching film 3a is an orthogonal line pattern formed to have a longitudinal direction orthogonal to a longitudinal direction of the sidewall pattern 1.

<FIG. 1G, FIG. 2G, and FIG. 3G>

Thereafter, a line pattern 4a is formed on the second etching film 3a. The line pattern 4a is a line pattern orthogonal to the sidewall pattern 1 (the interconnection pattern 11). The line pattern 4a is formed to have a longitudinal direction orthogonal to the longitudinal direction of the sidewall pattern 1.

<FIG. 1H, FIG. 2H, and FIG. 3H>

After the line pattern 4a is formed, the line pattern 4a is subjected to the slimming process, and thus a sliming pattern 4b is formed as a line pattern. The sliming pattern 4b is formed on the A-A line as illustrated in FIG. 2H but is not formed on the B-B line as illustrated in FIG. 3H. The sliming pattern 4b is formed to include a region in which the divisional linear pattern is to be formed. In other words, when the substrate 13 is viewed from the upper surface side, the divisional linear pattern is formed in a region in which the sliming pattern 4b is formed.

<FIG. 1I, FIG. 2I, and FIG. 3I>

Thereafter, etching is performed on the sliming pattern 4b and the second etching film 3a. As a result, a portion of the second etching film 3a present in a region substantially corresponding to the sliming pattern 4b remains as an orthogonal line pattern 3b, and a portion of the second etching film 3a in the remaining region is removed. Then, the sliming pattern 4b is also removed. Thus, the orthogonal line pattern 3b remains in the region substantially corresponding to the sliming pattern 4b, and the first etching film 5a remains in the region substantially corresponding to the second etching film 3a.

As a result, the orthogonal line pattern 3b and the first etching film 5a remain on the A-A line as illustrated in FIG. 2I, and the first etching film 5a remains on the B-B line as illustrated in FIG. 3I. The orthogonal line pattern 3b formed using the second etching film 3a is a line pattern orthogonal to the sidewall pattern 1(the interconnection pattern 11), and is formed to have a longitudinal direction orthogonal to the longitudinal direction of the sidewall pattern 1. The orthogonal line pattern 3b is formed to include a region in which the divisional linear pattern is to be formed.

<FIG. 1J, FIG. 2J, and FIG. 3J>

Thereafter, the upper surface side of the substrate 13 is planarized such that a carbon thin (CT) film 6a is formed on the orthogonal line pattern 3b and the first etching film 5a.

<FIG. 1K, FIG. 2K, and FIG. 3K>

Then, a resist pattern 7 is formed on the CT film 6a to cross the sidewall pattern 1 and the orthogonal line pattern 3b in an oblique direction. The resist pattern 7 is a pattern used to form a line pattern (an oblique line pattern which will be described later) that crosses the sidewall pattern 1 and the orthogonal line pattern 3b in the oblique direction. The resist pattern 7 is a linear pattern that passes above a first overlap region which is one of regions in which the sidewall pattern 1 overlaps the orthogonal line pattern 3b, and is arranged at a predetermined oblique angle (other than 90°) with respect to the sidewall pattern 1.

<FIG. 1L, FIG. 2L, and FIG. 3L>

Then, etching is performed on the resist pattern 7 and the CT film 6a. As a result, a portion of the CT film 6a present in the region substantially corresponding to the resist pattern 7 remains as an oblique line pattern 6b. Then, a portion of the CT film 6a in the region that does not correspond to the resist pattern 7 is removed. In other words, a portion of the CT film 6a below the resist pattern 7 remains, and the remaining portion of the CT film 6a is removed. Then, the entire resist pattern 7 is removed. Further, the orthogonal line pattern 3b below the CT film 6a remains.

Thus, the first etching film 5a remains over the entire surface of the substrate 13. Further, the orthogonal line pattern 3b is formed on the first etching film 5a, and the oblique line pattern (the oblique linear pattern) 6b obtained by patterning the CT film 6a is formed in the region, in which the resist pattern 7 has been formed, which is the region corresponding to the orthogonal line pattern 3b. The oblique line pattern 6b is formed to include a region in which the divisional linear pattern is to be formed.

<FIG. 1M, FIG. 2M, and FIG. 3M>

Thereafter, etching is performed on the oblique line pattern 6b and the orthogonal line pattern 3b. As a result, a portion of the orthogonal line pattern 3b of a region that does not cross the oblique line pattern 6b is removed, and a portion of the orthogonal line pattern 3b of a region crossing the oblique line pattern 6b remains as a divisional region pattern 9. Further, the oblique line pattern 6b remains. In other words, a portion of the orthogonal line pattern 3b present in the region that does not correspond to the oblique line pattern 6b is removed.

<FIG. 1N, FIG. 2N, and FIG. 3N)>

Further, etching is performed on the oblique line pattern 6b and the first etching film 5a. As a result, the oblique line pattern 6b is removed, and the oblique line pattern 9 formed in the region in which the oblique line pattern 6b overlaps the orthogonal line pattern 3b remains. Accordingly, the divisional region pattern 9 remains formed on the first etching film 5a. The divisional region pattern 9 is a parallelogram pattern formed in the second overlap region in which the orthogonal line pattern 3b overlaps the oblique line pattern 6b. The divisional region pattern 9 is a cut pattern formed in a region in which one linear pattern is to be divided in a region in which the divisional linear pattern is to be formed. In other words, the divisional linear pattern is formed such that one linear pattern is divided in a region corresponding to the divisional region pattern 9.

<FIG. 1O, FIG. 2O, and FIG. 3O>

Thereafter, etching is performed on the divisional region pattern 9 and the first etching film 5a. As a result, a portion of the first etching film 5a present in the region substantially corresponding to the region that does not correspond to the divisional region pattern 9 is removed. The etching further progresses, and thus a portion of the etching suppression material 2 present in the region that does not correspond to the divisional region pattern 9 is removed. Then, the divisional region pattern 9 is removed, and a portion of the etching suppression material 2 in the region corresponding to the divisional region pattern 9 remains as a divisional region pattern 5b. As a result, the divisional region pattern 5b using the etching suppression material 2 remains between the sidewall patterns 1.

<FIG. 1P, FIG. 2P, and FIG. 3P>

Then, etching is performed on the sidewall pattern 1 and the divisional region pattern 5b. As a result, a region of the processing target film 12 which is covered with neither the divisional region pattern 5b nor the sidewall pattern 1 is removed by etching. Then, a portion of the processing target film 12 present in the region corresponding to the sidewall pattern 1 or the divisional region pattern 5b remains, and the sidewall pattern 1 and the divisional region pattern 5b are removed by etching.

In other words, a portion of the processing target film 12 below the divisional region pattern 5b and a portion of the processing target film 12 below the sidewall pattern 1 remain. Further, a portion of the processing target film 12 which is neither below the divisional region pattern 5b nor the sidewall pattern 1, the sidewall pattern 1, and the divisional region pattern 5b are removed by etching.

<FIG. 1Q, FIG. 2Q, and FIG. 3Q>

Then, a metallic film is formed to cover a patterned processing target film 12, and thereafter etching is performed. Then, the processing target film 12 is removed by etching, and thus the interconnection pattern 11 is formed in a space pattern between the patterned processing target films 12. As a result, the interconnection pattern 11 is formed on the substrate 13.

The interconnection pattern 11 is a group of linear patterns interposed between neighboring linear patterns. In other words, the interconnection pattern 11 is the linear pattern group formed using the sidewall pattern 1, and includes a plurality of linear patterns arranged in the parallel direction. Among the interconnection patterns 11, when viewed from the top surface side, a linear pattern 10a remains divided by a region 5b′ (a region corresponding to the divisional region pattern 9) which is the region corresponding to the divisional region pattern 5b. As described above, the interconnection pattern 11 is formed such that the linear pattern 10a is divided by the region 5b′, and the interconnection pattern 11 other than the linear pattern 10a is not divided in midstream in the region other than the region 5b′.

FIG. 4 is a diagram for describing the oblique angle of the oblique line pattern. FIG. 4 is a top view of the substrate 13, and corresponds to FIG. 1L. In FIG. 4, for convenience of description, the sidewall pattern 1 and the etching suppression material 2 are illustrated as layers below the orthogonal line pattern 3b.

As illustrated in FIG. 4, the oblique line pattern 6b is a line pattern having a line width (the length in a short direction) of W, and is formed to have an oblique angle (a tilt angle) θ with respect to the orthogonal line pattern 3b having a line width of Y. The sidewall pattern 1 has a line width of S, and the etching suppression material 2 has a line width of L. Thus, the interconnection pattern 11 is a line/space pattern that has a line (a space before filling of the interconnection pattern 11) width of L and has a space (a line before filling of the interconnection pattern 11) width of S.

Next, a relation between the line width (hereinafter, referred to as an “oblique line width”) of the oblique line pattern 6b and the alignment accuracy will be described. FIG. 5 is a diagram for describing a relation between the oblique line width and the alignment accuracy. A horizontal axis of FIG. 5 represents the oblique line width of the oblique line pattern 6b, and a vertical axis of FIG. 5 represents the alignment accuracy between the oblique line pattern 6b and the orthogonal line pattern 3b. FIG. 5 illustrates relations 21 to 23 between the oblique angle and the alignment accuracy when Y is 32 nm, and each of L and S is 32 nm. The relations 21 to 23 are calculated under the assumption that a variation in dimension of the oblique line pattern 6b and the orthogonal line pattern 3b is ±10% from a desired value.

The relations 21 to 23 between the oblique angle and the alignment accuracy illustrate relations when the oblique angle θ is 90° (right angle), 70°, and 60°, respectively. A dimension accuracy permissible range of the oblique line width of the oblique line pattern 6b is calculated using the relations 21 to 23, a threshold value (permissible value) of the alignment accuracy, and the like.

Here, the dimension permissible range when the threshold value of the alignment accuracy is ±10 nm will be described. For example, the dimension accuracy permissible range is calculated using the oblique line width (W) corresponding to a maximum value of the relations 21 to 23 and a range (a line width permissible range) of the oblique line width (W) satisfying the threshold value. Specifically, the dimension accuracy permissible range is calculated using the following Formula (1).

Dimension permissible range=((line width permissible range)/2)/(oblique line width corresponding to maximum value) (1)

When the oblique angle θ is 60° (the relation 23), the oblique line width satisfying ±10 nm of the alignment accuracy (the threshold value) is about 28 nm to 32 nm. Further, when the oblique angle θ is 70° (the relation 22), the oblique line width satisfying ±10 nm of the alignment accuracy (the threshold value) is about 38 nm to 53 nm. Similarly, when the oblique angle θ is 90° (the relation 21), the oblique line width satisfying ±10 nm of the alignment accuracy (the threshold value) is about 58 nm to 69 nm.

Thus, when the oblique angle θ is 90°, the dimension permissible range of the oblique line width (W) is ±8%. Meanwhile, when the oblique angle θ is 70°, the dimension permissible range of the oblique line width (W) is ±13%. Further, when the oblique angle θ is 60°, the dimension permissible range of the oblique line width (W) is ±19%.

As described above, the oblique line width (W) in which the alignment accuracy becomes the maximum value depends on the oblique angle θ of the oblique line pattern 6b. Further, as described using the relations 21 to 23, a permissible amount (the line width permissible range) of the dimension variation can be mitigated by causing the oblique angle θ of the oblique line pattern 6b to slant.

Here, the line width permissible range of the oblique line pattern 6b allowing one linear pattern 10a to be divided will be described. First, the oblique line pattern 6b illustrated in FIG. 4 is defined as follows.

A variation in the line width of the oblique line pattern 6b is referred to as a w (for example, 10% of W).

An alignment accuracy of the exposure apparatus in the x direction is referred to as ±Z (10 nm in this example).

In order to fill the space region (between the sidewall pattern 1 and the sidewall pattern 1) (the position of the etching suppression material 2) in which the linear pattern 10a is to be formed with the metallic film and to divide the linear pattern 10a without affecting the shape of another linear pattern adjacent to the linear pattern 10a due to forming of the oblique line pattern 6b, the following Formulas (2) and (3) need to be satisfied.

L+2S<(W+w)/sin(θ)+Y/tan(θ)+2Z (2)

L>(W−w)/sin(θ)+Y/tan(θ)−2Z (3)

In Formulas (2) and (3), when the angle θ is 90°, a tan(θ) term is excluded. Here, an alignment error with the oblique line width (W) is calculated using the sum of the oblique line width (W) and the line width variation (w), but the alignment error with the oblique line width (W) may be calculated based on a variation in a normal distribution. Thus, since the alignment error with the oblique line width (W) can be converted by the sum of squares, the line width permissible range can be mitigated.

For example, when each of L and S is 32 nm, Z is 10 nm, w is 10% of W, and Y is 32 nm, 58 nm≦W≦69 nm needs to be satisfied at θ of 90°, and 33 nm≦W≦45 nm may be satisfied at θ of 60°.

Next, a relation between the oblique angle θ and the oblique line width (W) will be described. FIGS. 6A and 6B are diagrams for describing a relation between the oblique angle and the oblique line width. FIG. 6A illustrates a relation between the oblique angle θ and the oblique line width when the line width (the orthogonal line width) of the orthogonal line pattern 3b is 32 nm, and FIG. 6B illustrates a relation between the oblique angle θ and the settable oblique line width for each orthogonal line width. In FIG. 6A, a horizontal axis represents the oblique angle θ, and a vertical axis represents the oblique line width. In FIG. 6B, a horizontal axis represents the oblique angle, and a vertical axis represents the settable oblique line width (ΔW).

FIG. 6A illustrates a maximum value 25A and a minimum value 25B of the oblique line width (W). As illustrated in FIG. 6A, the maximum value 25A and the minimum value 25B of the oblique line width (W) change depending on the oblique angle θ.

FIG. 6B illustrates the settable oblique line widths (relations 26 to 28 between the oblique angle θ and the settable oblique line width) when the orthogonal line width (Y) is 32 nm, 42 nm, and 52 nm. The settable oblique line width (ΔW) is a value obtained by subtracting the minimum value from the maximum value of the oblique line width (W). The relations 26 to 28 are relations between the oblique angle θ and the settable oblique line width (ΔW) when the orthogonal line width (Y) is 32 nm, 42 nm, and 52 nm, respectively. As illustrated in FIG. 6B, the settable oblique line width (ΔW) changes depending on the oblique angle θ and the orthogonal line width.

For example, in the case in which each of L and S is 32 nm, Z is 10 nm, w is 10% of W, Y is 32 nm, and Z is 10 nm, when the angle θ is in a range of about 45° to 90°, the divisional region pattern 5b can be formed at a desired position with a high degree of alignment accuracy. Further, when the angle θ is 60°, it is possible to more easily increase the settable line width ΔW and makes a design robust to a dimension variation than when θ is 90°, that is, orthogonal.

The orthogonal line pattern 3b may be arranged at an angle other than a right angle with respect to the sidewall pattern 1. In other words, the orthogonal line pattern 3b may be arranged such that the orthogonal line pattern 3b crosses in a direction oblique with respect to the short direction of the sidewall pattern 1. In the following, the orthogonal line pattern arranged to cross in the direction oblique with respect to the short direction of the sidewall pattern 1 is referred to as a first oblique line pattern (a first oblique linear pattern), and the oblique line pattern 6b is referred to as a second oblique line pattern (a second oblique linear pattern).

FIGS. 7A and 7B are diagrams for describing oblique angles of the first and second oblique line patterns. FIG. 7A is a top view of the substrate 13 and corresponds to FIG. 1L. A description of the same dimension and angle as the dimension and angle illustrated in FIG. 4 will not be made. For convenience of description, the first etching film 5a is not illustrated in FIG. 7A.

As illustrated in FIG. 7A, the oblique line pattern 3c which is the first oblique line pattern is a line pattern in which the orthogonal line pattern 3b is rotated by an oblique angle θ₁. Thus, the oblique line pattern 3c is formed to have a longitudinal direction that forms the oblique angle θ₁ with the short direction of the sidewall pattern 1.

Further, the oblique line pattern 6b is formed to have a longitudinal direction that forms an oblique angle θ₂ with the short direction of the sidewall pattern 1. Thus, the oblique line pattern 6b is formed such that an oblique angle θ (θ₁+θ₂) is formed between the longitudinal direction of the oblique line pattern 6b and the longitudinal direction of the oblique line pattern 3c.

FIG. 7B illustrates a relation related to a dimension and angle between the oblique line pattern 3c which is the first oblique line pattern and the oblique line pattern 6b which is the second oblique line pattern. The oblique line pattern 3c illustrated in FIG. 7B is defined as follows.

A variation in the line width of the oblique line pattern 3c is referred to as a y (for example, 10% of Y).

An alignment accuracy of the exposure apparatus is referred to as ±Z₁ (10 nm in this example).

A variation in the line width of the oblique line pattern 6b is referred to as a w (for example, 10% of W).

An alignment accuracy of the exposure apparatus is referred to as ±Z₂ (10 nm in this example).

A parallelogram region in which the oblique line pattern 3c overlaps the oblique line pattern 6b is the divisional region pattern 9. An x component of the largest diagonal line C of the divisional region pattern 9 is a cut length Cx of the linear pattern 10a by the divisional region pattern 9, and thus an angle θc formed between the length of C and the short direction of the sidewall pattern 1 can be calculated using the following Formulas (4) and (5). The length of A (a first side of the parallelogram) in FIG. 7B is W/sin θ, and the length of B (a second side of the parallelogram) in FIG. 7B is Y/sin θ. In Formula (4), the law of cosines is applied to A, B, and C.

C=[{W²+Y²−2W·Y·cos(180−θ₁θ₂)}^{1/2}]/sin(θ₁+θ₂) (4)

θc={Arc tan(Y/C)−θ1 (5)

Although not specified in Formulas (4) and (5), W and Y are calculated using “W+w” and “Y+y” including respective variations, respectively.

Then, the cut length Cx can be calculated by assigning the angle θc calculated using Formula (5) to the following Formula (6):

Cx=C·cos θc (6)

In order to fill the space region (between the sidewall pattern 1 and the sidewall pattern 1) in which the linear pattern 10a is to be formed with the metallic film and to divide the linear pattern 10a without affecting the shape of another linear pattern adjacent to the linear pattern 10a due to forming of the oblique line pattern 6b, the following Formulas (7) and (8) need to be satisfied.

L+2S<C·cos θc+2Z₁+2Z₂ (7)

L>C·cos θc−2Z₁−2Z₂ (8)

Here, the oblique angle θ₁ and the alignment accuracy of the oblique line pattern 6b when the oblique angle θ₁ is given to the oblique line pattern 3c will be described. FIGS. 8A and 8B are diagrams for describing a relation between the oblique angle of the second oblique line pattern and the alignment accuracy of the second oblique line pattern. FIG. 8A is a diagram illustrating a relation between the oblique angle θ₂ of the oblique line pattern 6b and the alignment accuracy of the oblique line pattern 6b for each oblique angle θ₁ of the oblique line pattern 3c.

In FIG. 8A, a horizontal axis represents the oblique angle θ₂ of the oblique line pattern 6b, and a vertical axis represents the alignment accuracy of the oblique line pattern 6b. FIG. 8A illustrates relations 31A, 32A, and 33A between the oblique angle θ₂ and the alignment accuracy of the oblique line pattern 6b when the oblique angle θ₁ of the oblique line pattern 3c is 0°, 30°, and 45°, respectively.

A permissible range of the oblique angle θ₂ is decided according to a setting limit value of the alignment accuracy of the exposure apparatus. For example, in the case in which the setting limit value of the alignment accuracy of the exposure apparatus is 10 nm, when the oblique angle θ₁ is 0°, by setting the oblique angle θ₂ to be within an angle range 31B, the oblique line pattern 6b can be formed at a desired position (range).

Similarly, when the oblique angle θ₁ is 30°, by setting the oblique angle θ₂ to be within an angle range 32B, the oblique line pattern 6b can be formed at a desired position (range). Further, when the oblique angle θ₁ is 45°, by setting the oblique angle θ₂ to be within an angle range 33B, the oblique line pattern 6b can be formed at a desired position (range).

FIG. 8B is a diagram illustrating a relation between the oblique angle θ₂ of the oblique line pattern 6b and the permissible alignment accuracy range of the oblique line pattern 6b for each oblique angle θ₁ of the oblique line pattern 3c. The relation of FIG. 8B is calculated using the same condition as in FIG. 8A.

In FIG. 8B, a horizontal axis represents the oblique angle θ₂ of the oblique line pattern 6b, and a vertical axis represents an alignment accuracy error ΔCx of the oblique line pattern 6b (the maximum value of Cx−the minimum value of Cx). FIG. 8B illustrates relations 31C, 32C, and 33C between the oblique angle θ₂ and the alignment accuracy error when the oblique angle θ₁ of the oblique line pattern 3c is 0°, 30°, and 45°.

The alignment accuracy error of the oblique line pattern 6b differs according to the oblique angle θ₁ of the oblique line pattern 3c. As illustrated in FIG. 8B, as a value of the oblique angle θ₁ increases, an angle range settable to the oblique angle θ₂ increases. For example, when the alignment accuracy error (ΔCx) is desired to be suppressed to be 1.4 nm or less, the oblique angle θ₂ of the oblique line pattern 6b needs to be set to be about 50° or more when the oblique angle θ₁ is 0°. Meanwhile, when the oblique angle θ₁ is 30°, the oblique angle θ₂ of the oblique line pattern 6b may be set to be about 25° or more. Further, when the oblique angle θ₁ is 45°, the oblique angle θ₂ of the oblique line pattern 6b may be set to be about 8° or more.

Thus, for example, in the case in which each of L and S is 32 nm, W is 32 nm, w is 10% of W, Y is 32 nm, y is 10% of Y, and the oblique angle θ₁ is 45°, when the angle θ₂ is in a range of about 2° to 50°, the divisional region pattern 9 (the divisional region pattern 5b) can be formed at a desired position with a high degree of alignment accuracy.

As described above, in the present embodiment, the interconnection pattern 11 is formed using the orthogonal line pattern 3b and the oblique line pattern 6b, and thus the interconnection pattern 11 can be formed such that the linear pattern 10a interposed between neighboring linear patterns is divided in midstream with a high degree of accuracy. In other words, the space patterns (between the linear patterns 10a) can be connected to each other at a predetermined position (in the region corresponding to the divisional region pattern 9).

The sidewall process is not limited to the sidewall line transfer process described above, and may be a sidewall space transfer process. The sidewall space transfer process refers to a process of forming the same space pattern as the sidewall pattern by transferring the sidewall pattern onto a lower layer side.

For example, a process of forming a linear pattern which is divided in midstream is performed on a predetermined layer in a wafer process, and a semiconductor device (a semiconductor integrated circuit (IC)) is manufactured using this process. When each pattern described with reference to FIGS. 1A to 3Q is formed, an exposure process, a developing process, an etching process, a film forming process, and the like are repeated. For example, when the sidewall pattern 1 is formed, the exposure process is performed on the substrate 13 coated with a resist using a mask, and then the wafer is subjected to the developing process, so that the resist pattern (the core pattern 20a) is formed above the substrate 13. Then, the sidewall deposition film is deposited using the resist pattern as a core, and the sidewall pattern 1 is formed by removing the resist pattern. Thereafter, the oblique line pattern 6b and the orthogonal line pattern 3b are formed by performing the exposure process, the developing process, the etching process, the film forming process, and the like. Then, etching is performed on the oblique line pattern 6b and the orthogonal line pattern 3b, and thus the linear pattern 10a is formed. When a semiconductor device is manufactured, the exposure process, the developing process, the etching process, the film forming process, and the like are repeated for each layer.

The present embodiment has been described in connection with the example in which the linear pattern 10a formed using the sidewall process is divided. However, a linear pattern formed using a process other than the sidewall process may be divided. For example, the interconnection pattern 11 may be formed such that a linear pattern formed using an imprint lithography or a directed self assembly (DSA) is divided.

Further, the present embodiment has been described in connection with the example in which a group of a plurality of interconnection patterns is used as a linear pattern. However, a group of a plurality of space patterns may be used as the linear pattern. For example, by forming patterns of the processing target film 12 illustrated in FIG. 1P, a space (a region represented by the substrate 13 in FIG. 1P) between the patterns of the processing target film 12 is formed as the linear space pattern. In this case, the linear space pattern is divided in midstream by the patterns of the processing target film 12. By causing the processing target film 12 to remain as the interconnection layer, each linear space pattern can be formed such that the linear space pattern between the interconnection layers is divided in midstream. In other words, the neighboring linear line patterns (the interconnection patterns formed in the interconnection layer) can be connected to each other at a predetermined position (the region 5b′).

Further, the divisional region pattern 5b may be formed to divide an arbitrary number of linear patterns without affecting the shape of a linear pattern adjacent to the linear pattern to be divided.

Further, a plurality of patterns may be simultaneously formed as each of the orthogonal line pattern 3b, the oblique line pattern 6b, the oblique line pattern 3c, and the like. In this case, the divisional region pattern 5b can be formed at a plurality of positions.

Further, any of the orthogonal line pattern 3b and the oblique line pattern 6b may be first formed. When the oblique line pattern 6b is first formed, the oblique line pattern is formed by the process described with reference to FIGS. 1G to 1I. Then, the orthogonal line pattern is formed by the process described with reference to FIGS. 1K and 1L. As a result, the orthogonal line pattern 3b is formed at the position of the oblique line pattern 6b illustrated in FIG. 1L, and the oblique line pattern 6b is formed at the position of the orthogonal line pattern 3b illustrated in FIG. 1I. Similarly, any of the oblique line pattern 3c and the oblique line pattern 6c may be first formed.

The process illustrated in FIG. 1J may not be performed. Specifically, the orthogonal line pattern 3b is formed by the first lithography described with reference to FIG. 1G, and the oblique line pattern 6b is formed by the second lithography without performing the developing process. Thereafter, the developing process is performed on the orthogonal line pattern 3b and the oblique line pattern 6b. As a result, the shape of the divisional region pattern 9 is formed by the resist according to the cross-point region at the stage of lithography. Then, the resist pattern is etched once, and so the divisional region pattern 9 is formed. Even in this case, the orthogonal line pattern 3b may be formed after the oblique line pattern 6b is formed.

Further, after the interconnection pattern is formed, the interconnection pattern is divided using the orthogonal line pattern 3b and the oblique line pattern 6b, and thus the linear pattern 10a is formed. In this case, a space between the interconnection patterns is filled with the etching suppression material 2 to planarize the substrate 13, and thereafter the first etching film 5a and the second etching film 3a are formed. Further, each of the orthogonal line pattern 3b and the oblique line pattern 6b is formed as a hole pattern (groove pattern) which extends in a line form. Then, the interconnection pattern formed at the position at which the orthogonal line pattern 3b crosses the oblique line pattern 6b is etched from the orthogonal line pattern 3b and the oblique line pattern 6b, so that the divided linear pattern 10a is formed.

Similarly, the linear pattern 10a may be divided by connecting the interconnection patterns using the orthogonal line pattern 3b and the oblique line pattern 6b after the space pattern is formed by the processing target film 12.

As described above, according to the first embodiment, the resist pattern 7 crossing in the direction oblique with respect to the sidewall pattern 1 and the orthogonal line pattern 3b is formed, and the oblique line pattern 6b is formed using the resist pattern 7. Then, etching is performed on the oblique line pattern 6b and the orthogonal line pattern 3b to form the divisional region pattern 5b, and the interconnection pattern 11 is formed using the divisional region pattern 5b. Thus, each linear pattern can be formed such that the linear pattern interposed between the neighboring linear patterns is divided with a high degree of accuracy without affecting the shapes of the neighboring linear patterns.

### Second Embodiment

Next, a second embodiment of the invention will be described with reference to FIGS. 9A to 10G. In the second embodiment, a line pattern is formed using the core pattern 20a in the region in which the divisional region pattern is to be formed, and then the divisional region pattern is formed using the line pattern.

FIGS. 9A to 9G and FIGS. 10 to 10G are diagrams for describing a pattern forming process according to the second embodiment. FIGS. 9A to 9G are top views of a substrate for describing the pattern forming process according to the second embodiment, and FIGS. 10A to 10G are A-A cross-sectional views of a substrate for describing the pattern forming process according to the second embodiment. In the present embodiment, the interconnection pattern 11 is formed by the same pattern forming process as the first embodiment.

FIGS. 10A to 10G correspond to FIGS. 9A to 9G, respectively. An example in which the divisional linear pattern is formed on the A-A line (the A-A cross section) will be described with reference to FIGS. 9A to 9G and FIGS. 10A to 10G. Here, processes to be described with reference to FIGS. 9A to 9D correspond to the processes described with reference to FIGS. 1A to 1D, respectively. Similarly, processes to be described with reference to FIGS. 10A to 10D correspond to the processes described with reference to FIGS. 2A to 2D, respectively. Further, processes to be described with reference to FIGS. 9E, 9F, and 9G correspond to the processes described with reference to FIGS. 1H, 1K, and 1Q, respectively. Similarly, processes to be described with reference to FIGS. 10E, 10F, and 10G correspond to the processes described with reference to FIGS. 2H, 2K, and 2Q, respectively.

<FIG. 9A and FIG. 10A>

After a processing target film 12 is formed on a substrate 13, a core pattern 20a used in the sidewall process is formed on the processing target film 12. In the present embodiment, core patterns 20a and 20a at both sides of the position at which a divided linear pattern is to be formed are connected by a line pattern. Specifically, the core patterns 20a and 20a are connected to each other such that a line pattern 20a′ extending in the short direction of the core pattern 20a is arranged between the core patterns 20a and 20a. In other words, an H-shaped pattern is formed by the core patterns 20a and the line pattern 20a′ extending in the short direction. As described above, the line pattern 20a′ that connects the two neighboring linear patterns (the core patterns 20a) among the core patterns 20a in the short direction is formed.

The line pattern 20a′ is a pattern having the same width as the core pattern 20a. Among sides of the line pattern 20a′, the length of a side parallel to the short direction of the core pattern 20a is the same as a space width between the core patterns 20a and 20a, and the length of a side parallel to the longitudinal direction of the core pattern 20a can be adjusted according to a desired division width. Further, the length of a side parallel to the longitudinal direction of the line pattern 20a′ is the same as, for example, the width of the core pattern 20a in the short direction.

<FIG. 9B and FIG. 10B>

After the line pattern 20a′ is formed, the core pattern 20a is subjected to a slimming process, and thus a slimming pattern 20b is formed.

<FIG. 9C and FIG. 10C>

Then, a sidewall deposition film is deposited to cover the slimming pattern 20b. Thereafter, the sidewall deposition film is etched by anisotropic etching, and thus a sidewall pattern 1 is formed from the sidewall deposition film. The sidewall pattern 1 is formed on a side surface of the slimming pattern 20b. Thus, in the present embodiment, the sidewall pattern 1 is formed even on a side surface of a pattern obtained by performing the slimming process on the line pattern 20a′.

<FIG. 9D and FIG. 10D>

Then, the slimming pattern 20b is subjected to wet etching. As a result, the slimming pattern 20b is removed, and the sidewall pattern 1 remains on the processing target film 12. At this time, the sidewall pattern 1 includes the pattern corresponding to the core pattern 20a and the pattern corresponding to the line pattern 20a′. Among the sidewall patterns 1, the pattern corresponding to the line pattern 20a′ is a connection pattern that connects the two neighboring linear patterns among the sidewall patterns 1 in the short direction. The connection pattern is formed to include a part of a parallelogram region in which a divisional region pattern 5c which will be described later is to be formed and a region at an outer side further than the divisional region pattern 5c.

<FIG. 9E, FIG. 10E>

In FIG. 9E corresponding to FIG. 1H, a film and a pattern other than the sidewall pattern 1 and the sliming pattern 4b are not illustrated. Further, in FIG. 10E corresponding to FIG. 2H, the first etching film 5a, the second etching film 3a are not illustrated.

After the sidewall pattern 1 remains on the processing target film 12, the same processes as in FIGS. 1E to 1G described in the first embodiment are performed. As a result, the line pattern 4a (not illustrated here) is formed on the second etching film 3a.

The line pattern 4a is a line pattern orthogonal to the longitudinal direction of the sidewall pattern 1 (the interconnection pattern 11), and is formed to pass above the inner side region of the line pattern 20a′. After the line pattern 4a is formed, the line pattern 4a is subjected to the slimming process, and thus the sliming pattern 4b is formed as a line pattern. As a result, the sliming pattern 4b is formed on the A-A line as illustrated in FIG. 9E. The sliming pattern 4b is formed to include a part of the region in which the divisional linear pattern is to be formed, and undertakes the same role as the orthogonal line pattern 3b described in the first embodiment (FIG. 1I). The slimming process may not be performed.

<FIG. 9F and FIG. 10F>

In FIG. 9F corresponding to FIG. 1K, a film other than the sidewall pattern 1, the sliming pattern 4b, and the resist pattern 7 is not illustrated. Further, in FIG. 10F corresponding to FIG. 2K, the first etching film 5a, the orthogonal line pattern 3b, and the CT film 6a are not illustrated.

After the sliming pattern 4b is formed, the same processes as in FIGS. 1I and 1J described in the first embodiment are performed. Further, the resist pattern 7 which crosses the sidewall pattern 1 and the sliming pattern 4b in the oblique direction is formed on the CT film 6a. Here, the resist pattern 7 undertakes the same role as the oblique line pattern 6b described in the first embodiment (FIG. 1L).

<FIG. 9G and FIG. 10G>

Thereafter, the same processes as in FIGS. 1L to 1P described in the first embodiment are performed. As a result, the divisional region pattern 9 is formed in the region in which the resist pattern 7 overlaps the sliming pattern 4b. Then, etching is performed on the divisional region pattern 9. As a result, a portion of the etching suppression material 2 in the region corresponding to the divisional region pattern 9 remains as the divisional region pattern 5c (not illustrated), and the remaining portion of the etching suppression material 2 is removed.

Then, etching is performed on the divisional region pattern 5c and the sidewall pattern 1. As a result, a region which is covered with none of the divisional region pattern 5c and the sidewall pattern 1 is removed by etching. Specifically, a portion of the processing target film 12 above which the divisional region pattern 5c is not formed and a portion of the processing target film 12 above which the sidewall pattern 1 is not formed are removed. Here, the sidewall pattern 1 also includes the connection pattern formed using the line pattern 20a′. Further, the divisional region pattern 5c and the sidewall pattern 1 are removed by etching. Thus, a portion of the processing target film 12 in the region corresponding to the divisional region pattern 5c and a portion of the processing target film 12 in the region corresponding to the sidewall pattern 1 remain.

Then, a metallic film or the like is formed to cover the patterned processing target film 12, and thereafter etching is performed. Then, the processing target film 12 is removed by etching, and thus the interconnection pattern 11 is formed in a space pattern between the patterned processing target films 12. As a result, the interconnection pattern 11 is formed on the substrate 13.

The interconnection pattern 11 is a group of linear patterns interposed between neighboring linear patterns. Among the interconnection patterns 11, when viewed from the top surface side, a linear pattern 10b remains divided by a region 5c′ corresponding to the divisional region pattern 5c and a region 20a″ of the connection pattern formed using the line pattern 20a′. Further, the linear patterns adjacent to the linear pattern 10b are formed to have a convex pattern at the region 5c′ side near the region 5c′, and the linear patterns adjacent to the linear pattern 10b are divided by the region 5c′.

In the present embodiment, the line pattern 20a′ is formed between the core patterns 20a, and the divisional region pattern 5c is formed in the region adjacent to the line pattern 20a′. Then, the linear pattern 10b is formed using the divisional region pattern 5c and the sidewall pattern 1 formed using the line pattern 20a′. For this reason, the space region (division length) between the divided linear patterns 10b is decided by the pattern region (position) of the sidewall pattern 1 formed using the line pattern 20a′.

As described above, according to the second embodiment, the linear patterns can be formed such that one linear pattern 10a is divided in midstream with a high degree of accuracy, similarly to the first embodiment. Further, since the interconnection pattern is formed using the line pattern 20a′ between the core patterns 20a and the divisional region pattern 5c, the line pattern 4a (the sliming pattern 4b) used for the orthogonal line pattern 3b can be easily aligned. Further, the resist pattern 7 can be easily aligned.

### Third Embodiment

Next, a third embodiment of the invention will be described with reference to FIGS. 11A and 13B. In the third embodiment, the same patterns as the oblique line pattern 6b and the oblique line pattern 3c described in FIGS. 7A and 7B of the first embodiment are formed using a resist pattern, and the divisional region pattern is formed using the formed resist pattern. In other words, the divisional region pattern is formed in the cross-point region of the oblique line pattern 6b and the oblique line pattern 3c.

FIGS. 11A to 11D and 12 are diagrams for describing a pattern forming process according to the third embodiment. FIGS. 11A to 11D are top views of a substrate for describing the pattern forming process according to the third embodiment, and FIG. 12 is an AA cross-sectional view of a substrate for describing the pattern forming process according to the third embodiment. Here, a description of the same pattern forming process as in the first or second embodiment will not be made.

FIG. 12 corresponds to FIG. 11B. An example in which the divisional linear pattern is formed on the A-A line (the AA cross section) will be described with reference to FIGS. 11A to 11D and 12.

<FIG. 11A>

In FIG. 11A, a first etching film 5a and a second etching film 3a are not illustrated. Through the same process as in FIGS. 1A to 1E described in the first embodiment, a sidewall pattern 1 is formed on a processing target film 12, and a space between the sidewall patterns 1 is filled with an etching suppression material 2. Then, through the same process as in FIGS. 1F and 1G, a first etching film 5a and a second etching film 3a are formed. Then, a first oblique line pattern 4R is formed on an upper surface side (on first and second etching films 5a and 3a) of the sidewall pattern 1 and the etching suppression material 2 by a first lithography, and a second oblique line pattern 7R is formed by a second lithography without performing a developing process. As a result, the shape of a divisional region pattern 9 is formed by a resist according to the cross-point region at the stage of lithography.

The first oblique line pattern 4R has the same shape (the oblique angle) as the oblique line pattern 3c, and is arranged at the same arrangement position when viewed from the upper surface side. Further, the second oblique line pattern 7R has the same shape (the oblique angle) as the oblique line pattern 6b, and is arranged at the same arrangement position when viewed from the upper surface side. In other words, the first and second oblique line patterns 4R and 7R are formed such that the divisional region pattern is formed in the cross-point region of the first oblique line pattern 4R and the second oblique line pattern 7R.

Further, each of the first oblique line pattern 4R and the second oblique line pattern 7R has an oblique angle in a range of 0° to 90°. In this case, the first and second oblique line patterns 4R and 7R are arranged such that the first oblique line pattern 4R and the second oblique line pattern 7R do not extend in the same direction.

In other words, the first and second oblique line patterns 4R and 7R are arranged such that the oblique angle θ(θ₁+θ₂) illustrated in FIG. 7B does not become 0°. Further, the first and second oblique line patterns 4R and 7R are arranged such that the angle θ₁ does not become 0°, and the angle θ₂ does not become 90°. In other words, at least one of a first oblique angle which is the oblique angle of the first oblique line pattern 4R and a second oblique angle of the oblique angle of the second oblique line pattern 7R is set to an angle other than a right angle. As a result, the cross-point region becomes a parallelogram. FIG. 11A illustrates an example in which the oblique angle of the first oblique line pattern 4R is the same as the oblique angle of the second oblique line pattern 7R, and the cross-point region has a rhombus shape.

<FIG. 11B and FIG. 12>

In FIGS. 11B and 12 corresponding to FIGS. 1N and 2N, respectively, the first etching film 5a is not illustrated. The first and second oblique line patterns 4R and 7R are formed, the shape of the divisional region pattern 9 is formed by the resist according to the cross-point region, and then etching is performed. As a result, the divisional region pattern 9 is formed in the cross-point region of the first and second oblique line patterns 4R and 7R. Here, when viewed from the upper surface side, the divisional region pattern 9 has substantially the same shape as the cross-point region, and a parallelogram having a rhombus shape or the like.

Thereafter, the divisional region pattern 9 is subjected to the slimming process as necessary. In the present embodiment, since the divisional region pattern 9 has the parallelogram shape, an apex portion (a protruding portion) of the parallelogram can be easily slimmed. Thus, the dimension of the divisional region pattern 9 can be easily adjusted.

<FIG. 11C>

Thereafter, etching is performed on the divisional region pattern 9 and the first etching film 5a. As a result, a portion of the etching suppression material 2 in the region that does not correspond to the divisional region pattern 9 is removed. Further, the divisional region pattern 9 is removed, and a portion of the etching suppression material 2 in the region corresponding to the divisional region pattern 9 remains as the divisional region pattern 5c. As a result, a divisional region pattern 5d using the etching suppression material 2 remains between the sidewall patterns 1.

<FIG. 11D>

Then, etching is performed on the sidewall pattern 1 and the divisional region pattern 5d. As a result, a portion of the processing target film 12 which is covered with none of the sidewall pattern 1 and the divisional region pattern 5d is removed by etching. In other words, a portion of the processing target film 12 below the divisional region pattern 5d and a portion of the processing target film 12 below the sidewall pattern 1 remain. Further, a portion of the processing target film 12 which is not covered with the divisional region pattern 5d and the sidewall pattern 1, the sidewall pattern 1, and the divisional region pattern 5d are removed by etching.

Then, a metallic film or the like is formed to cover the patterned processing target film 12, and thereafter etching is performed. Then, the processing target film 12 is removed by etching, and thus the interconnection pattern 11 is formed in a space pattern between the patterned processing target films 12. As a result, the interconnection pattern 11 is formed on the substrate 13.

The interconnection pattern 11 is a group of linear patterns interposed between neighboring linear patterns. Among the interconnection patterns 11, when viewed from the top surface side, a linear pattern 10c remains divided in midstream by the region (the cross-point region which is the region corresponding to the divisional region pattern 9) corresponding to the divisional region pattern 5d.

In the present embodiment, since the dimension of the divisional region pattern 9 can be easily adjusted, an inter-space distance between the divided linear patterns 10c can be easily adjusted with a high degree of accuracy. Further, the same pattern as the oblique line pattern 6b may be used as the first oblique line pattern, and the same pattern as the oblique line pattern 3c may be used as the second oblique line pattern.

The present embodiment has been described in connection with the example in which etching is performed on the first and second oblique line patterns 4R and 7R. However, etching may be performed twice. That is, etching may be performed on the first oblique line pattern 4R, and etching may be performed on the second oblique line pattern. In this case, after the first oblique line pattern 4R is formed, etching is performed on the first oblique line pattern 4R. Thereafter, a new resist is coated to form the second oblique line pattern 7R, and etching is performed on the second oblique line pattern 7R.

Meanwhile, the oblique line pattern such as the first oblique line pattern 4R, the second oblique line pattern 7R, the oblique line patterns 6b (the resist pattern 7) and 3c described in the first embodiment, and the resist pattern 7 described in the second embodiment may be formed in a misaligned state.

FIGS. 13A and 13B are diagrams for describing misalignment of the oblique line pattern. FIG. 13A is a top view of the substrate 13 when the resist pattern 7 described in the first embodiment is formed in a state in which the resist pattern 7 remains misaligned from an arrangement position 61 which is a normal position to an arrangement position 62. For convenience of description, FIG. 13A illustrates the orthogonal line pattern 3b and the sidewall pattern 1 as a layer below the resist pattern 7 and a layer below the orthogonal line pattern 3b, respectively.

FIG. 13B illustrates the shape of the interconnection pattern 11 formed using the misaligned resist pattern 7. Here, when the interconnection pattern 11 is formed using the resist pattern 7 causing the misalignment illustrated in FIG. 13A, a protruding pattern 63 may be formed in the divided linear pattern 10b as illustrated in FIG. 13B. The protruding pattern 63 is a pattern of a substantially triangular shape extending from one of the divided linear patterns 10b. The protruding pattern 63 extends from one of the divided linear patterns 10b toward the other pattern side.

Even in this case, the divided linear pattern 10b is formed unless one of the divided linear patterns 10b is connected with the other.

As described above, according to the third embodiment, since the divisional region pattern 5d is formed using the first and second oblique line patterns 4R and 7R as the oblique line pattern, the linear pattern 10c which is divided in midstream can be easily formed with a high degree of accuracy.

### Fourth Embodiment

Next, a fourth embodiment of the invention will be described with reference to FIGS. 14A to 17C. In the fourth embodiment, a pillar pattern having an upper surface (bottom surface) pattern of an elliptical shape is formed as the divisional region pattern.

FIGS. 14A to 15B are diagrams for describing a pattern forming process according to the fourth embodiment. FIGS. 14A and 14B are top views of a substrate for describing the pattern forming process according to the fourth embodiment, and FIGS. 15A and 15B are AA cross-sectional views of a substrate for describing the pattern forming process according to the fourth embodiment. FIG. 16 is a flowchart illustrating the pattern forming process according to the fourth embodiment. Here, a description of the same pattern forming process as in the first to third embodiments described with reference to FIGS. 1A to 3Q and FIGS. 9A to 12 will not be made.

FIGS. 15A and 15B correspond to FIGS. 14A and 14B, respectively. An example in which the divisional linear pattern is formed on the A-A line (the AA cross section) will be described with reference to FIGS. 14A to 15B.

<FIG. 14A and FIG. 15A>

Through the same process as in FIGS. 1A to 1E and FIGS. 2A to 2E described in the first embodiment, a sidewall pattern 1 is formed on a processing target film 12, and a space between the sidewall patterns 1 is filled with an etching suppression material 2. Then, a pillar pattern 16 which is the resist pattern is formed on the sidewall pattern 1 and the etching suppression material 2 (step S10).

The pillar pattern 16 is a columnar pattern having an upper surface and a bottom surface of an elliptical shape. The pillar pattern 16 is formed to have substantially the same center position as a center position (of one etching suppression material 2) between the sidewall patterns 1. Specifically, the pillar pattern 16 is formed on an inter-pattern region including a region between the sidewall patterns 1 (a region of one etching suppression material 2) and regions of the two sidewall patterns 1 adjacent to the region of the etching suppression material 2. The pillar pattern 16 may protrude from the region of the etching suppression material 2 adjacent to the two sidewall patterns 1. An elliptical pattern of the pillar pattern 16 has a long axis direction parallel to the short direction of the sidewall pattern 1 and a short axis direction parallel to the longitudinal direction of the sidewall pattern 1.

After the pillar pattern 16 is formed, the pillar pattern 16 which is the first elliptical pattern is subjected to the slimming process, and thus a pillar pattern 15 which is a second elliptical pattern is formed. At this time, a slimming process amount of the pillar pattern 16 is calculated based on the forming position (the misalignment amount on a space between the sidewall patterns 1) and the size of the pillar pattern 16 so that the pillar pattern 15 can be formed at a desired position with a desired size (step S20). Further, the slimming process amount may be calculated under the assumption that there is no dimension deviation in the size of the pillar pattern 16. Alternatively, the size of the pillar pattern 16 may be measured, and the slimming process amount may be calculated based on the measured size.

Here, the slimming process amount is set to a value that allows the slimmed pillar pattern 15 to connect the etching suppression materials 2 with each other on the first sidewall pattern 1 and allows the pillar pattern 15 to be formed at the position at which the pillar pattern 15 does not contact the sidewall pattern 1 arranged adjacent to the first sidewall pattern 1.

Then, the pillar pattern 16 is slimmed by the calculated slimming process amount (step S30), and thus a desired pillar pattern 15 is formed. As described above, the pillar pattern 15 is formed on the processing target film 12 using advanced process control (APC). In the present embodiment, the pillar pattern serves as the divisional region pattern (step S40).

<FIG. 14B and FIG. 15B)>

Thereafter, through the same process as in FIGS. 11C and 11D described in the third embodiment, the interconnection pattern 11 is formed on the substrate 13. Among the interconnection patterns 11, when viewed from the upper surface side, a linear pattern 10d remains divided in midstream by the region corresponding to the pillar pattern 15.

In the present embodiment, since the dimension of the pillar pattern 15 serving as the divisional region pattern can be easily adjusted, the inter-space distance between the divided linear patterns 10d can be easily adjusted with a high degree of accuracy.

Next, a relation between the elliptical shape of the pillar pattern 16 and the alignment accuracy will be described. FIGS. 17A to 17C are diagrams for describing a relation between the pillar pattern dimension and the alignment accuracy. FIG. 17A is a top view of the pillar pattern 16. FIG. 17B is a top view of the interconnection pattern 11 in which the linear pattern 10d is formed. FIG. 17C illustrates a relation between the pillar pattern dimension and the alignment accuracy (permissible value).

Here, a major axis X1 of the pillar pattern 16 when a minor axis Y1 of the pillar pattern 16 (of the elliptical shape) is 42 nm as illustrated in FIG. 17A will be described. When the minor axis Y1 of the pillar pattern 16 is set to 42 nm, the linear pattern 10d is divided apart by a distance Y2 of 42 nm, as illustrated in FIG. 17B. In other words, the linear pattern 10d is divided by the space region of the substantially same region as the pillar pattern 16.

Here, a line/space pattern in which the sidewall pattern 1 is a line pattern, and a region between the sidewall patterns 1 is a space region will be described in connection with the alignment accuracy on line/space patterns of 32 nm, 42 nm, and 52 nm. For example, the line/space pattern of 32 nm refers to a line/space pattern in which each of a pattern width (in the short direction) of the line pattern and a pattern width (in the short direction) of the space pattern is 32 nm.

In FIG. 17C, a horizontal axis represents an X1 dimension of the elliptical shape of the pillar pattern 16, and a vertical axis represents the alignment accuracy between the pillar pattern 16 (the pillar pattern 15 before the slimming process) and the sidewall pattern 1. A relation 36 refers to a relation between the X1 dimension of the pillar pattern 16 and the alignment accuracy when the sidewall pattern 1 is formed by the line/space pattern of 32 nm. Similarly, relations 37 and 38 refer to relations between the dimension of the pillar pattern 16 and the alignment accuracy when the sidewall pattern 1 is formed by the line/space patterns of 42 nm and 52 nm, respectively.

Meanwhile, the relation 35 represents the alignment accuracy when the elliptical shape of the pillar pattern 16 a true circle (X1=Y1=42 nm). Here, when the elliptical shape of the pillar pattern 16 is a true circle, the alignment accuracy is 10 nm.

Further, in case of the line/space pattern of 32 nm, when X1 is in a range of about 43 nm to 76 nm, the pillar pattern 16 can be formed with the alignment accuracy (permissible range) of 10 nm or more.

Further, in case of the line/space pattern of 42 nm, when X1 is in a range of about 51 nm to 107 nm, the pillar pattern 16 can be formed with the alignment accuracy (permissible range) of 10 nm or more.

Further, in case of the line/space pattern of 52 nm, when X1 is in a range of about 63 nm to 135 nm, the pillar pattern 16 can be formed with the alignment accuracy of 10 nm or more.

Further, when the elliptical shape of the pillar pattern 16 is not a true circle, the alignment accuracy has a predetermined peak value. In other words, there exists the X1 dimension that causes the alignment accuracy to become maximum. The peak value or the X1 dimension causing the peak value represents a value that differs according to the dimension of the line/space pattern.

For example, in case of the line/space pattern (the relation 36) of 32 nm, when the pillar pattern 16 is formed with the X1 dimension of about 55 nm, the alignment accuracy is allowed up to about 21 nm. Further, in case of the line/space pattern (the relation 37) of 42 nm, when the pillar pattern 16 is formed with the X1 dimension of about 70 nm, the alignment accuracy is allowed up to about 27.5 nm. Further, in case of the line/space pattern (the relation 38) of 52 nm, when the pillar pattern 16 is formed with the X1 dimension of about 90 nm, the alignment accuracy is allowed up to about 34 nm.

As described above, when the pillar pattern 16 is formed to have the elliptical shape in which the dimension in the short direction is larger than the dimension in the longitudinal direction of the sidewall pattern 1, the alignment accuracy between the pillar pattern 16 (the pillar pattern 15 before the slimming process) and the sidewall pattern 1 is improved. Further, when the pillar pattern 16 is formed to have the elliptical shape, the pillar patterns 15 and 16 can be prevented from collapsing.

The present embodiment has been described in connection with the example in which the pillar pattern 15 is formed as the divisional region pattern, but the linear pattern 10d may be formed using a hole pattern. In other words, any of a columnar pattern and a hole pattern may be formed as the pillar pattern 15. In this case, the hole pattern is formed such that the hole pattern is formed at the position of the pillar pattern 15, and the linear pattern 10d is divided by the hole pattern.

Specifically, after the interconnection pattern 11 is formed, a space between the interconnection pattern 11 is filled with the etching suppression material 2 or the like. Thereafter, a resist hole pattern is formed on a portion of the interconnection pattern 11 corresponding to the position of the pillar pattern 16, and the slimming process (a process of forming a sidewall film or the like on the outer circumference of the hole pattern) is performed to reduce a hole diameter of the hole pattern. At this time, a slimming process amount is calculated based on the size and the forming position of the hole pattern, and the slimming process is performed using the slimming process amount. Then, etching is performed on the hole pattern, and so one or more of the interconnection patterns 11 (the linear pattern 10d) is divided by the region of the elliptical shape.

Further, the present embodiment has been described in connection with the example in which the linear pattern is the interconnection pattern, but the linear pattern may be the space pattern. In this case, the center position of the hole pattern having the upper surface of the elliptical shape is between the etching suppression material 2 and the etching suppression material 2 (the substantially same position as the center position of one sidewall pattern 1).

Specifically, after the interconnection pattern 11 is formed, a space between the interconnection patterns 11 is filled with the etching suppression material 2 or the like. Thereafter, a resist hole pattern is formed on a portion of the interconnection pattern 11 corresponding to the position of the pillar pattern 16, and the slimming process is performed to reduce a hole diameter of the hole pattern. At this time, a slimming process amount is calculated based on the size and the forming position of the hole pattern, and the slimming process is performed using the slimming process amount. Then, etching is performed on the hole pattern, and so that one or more of the etching suppression materials 2 are divided by the region of the elliptical shape. Further, the region of the elliptical shape is filled with the interconnection pattern, and so the interconnection patterns 11 are connected to each other by the interconnection pattern in the elliptical shape region. As a result, one space pattern is divided by the interconnection pattern in the elliptical shape region.

Further, the present embodiment has been described in connection with the example in which the pillar pattern 15 has the upper surface of the elliptical shape. However, the pillar pattern 15 may have the upper surface of a quadrangular shape such as a square shape, a rectangular shape, a parallelogram, or a rhombus shape. In this case, the pillar pattern 15 is formed such that the size in the short direction of the sidewall pattern 1 is larger than the size in the longitudinal direction of the sidewall pattern 1.

Further, the pillar pattern 15 may have the upper surface of a polygonal shape of a pentagonal or more shape. Even in this case, the pillar pattern 15 is formed such that the size in the short direction of the sidewall pattern 1 is larger than the size in the longitudinal direction of the sidewall pattern 1.

As described above, according to the fourth embodiment, the pillar pattern 16 is formed on the elliptical shape region, and the pillar pattern 16 is slimmed by a predetermined amount based on the size and the forming position of the pillar pattern 16. Thus, the pillar pattern 15 serving as the divisional region pattern can be easily formed with a desired size at a desired position. Further, since the interconnection pattern 11 is formed using the pillar pattern 15, the linear pattern 10d which is divided in midstream can be easily formed with a high degree of accuracy.

As described above, according to the first to fourth embodiments, linear patterns can be formed such that one or more linear patterns interposed between neighboring linear patterns are divided in midstream with a high degree of accuracy.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of forming a pattern, comprising:
forming a plurality of linear patterns arranged in a parallel direction as a first parallel linear pattern;
forming a linear pattern arranged above the first parallel linear pattern at a first oblique angle with respect to the first parallel linear pattern as a first oblique linear pattern;
forming a linear pattern that passes above a first overlap region which is one of regions in which the first parallel linear pattern overlaps the first oblique linear pattern and is arranged at a second oblique angle with respect to the first parallel linear pattern as a second oblique linear pattern;
forming a pattern, using the first and second oblique linear patterns, in a second overlap region in which the first oblique linear pattern overlaps the second oblique linear pattern; and
forming a second parallel linear pattern using the pattern such that a plurality of second parallel linear patterns which are formed using the first parallel linear pattern and arranged in a parallel direction are divided by the second overlap region, and each of the second parallel linear patterns is not divided in midstream in a region other than the second overlap region,
wherein at least one of the first and second oblique angles is an angle other than a right angle.

2. The method according to claim 1,
wherein the first parallel linear pattern is formed using a sidewall process.

3. The method according to claim 1,
wherein when the first parallel linear pattern is formed, a connection pattern that connects two neighboring linear patterns among the first parallel linear patterns in a short direction is formed to include a part of a region in which the pattern is formed and a region at an outer side further than the region, and
the second parallel linear pattern is formed to be divided by a region in which the second overlap region and the connection pattern are formed.

4. The method according to claim 1,
wherein the first oblique angle or the second oblique angle is a right angle.

5. The method according to claim 1,
wherein each of the first and second parallel linear patterns is a group of a plurality of line patterns.

6. The method according to claim 1,
wherein each of the first and second parallel linear patterns is a group of a plurality of space patterns.

7. The method according to claim 1,
wherein at least one of the first and second oblique linear patterns is a plurality of line patterns.

8. The method according to claim 1,
wherein at least one of the first and second oblique linear patterns is a plurality of space patterns.

9. The method according to claim 1,
wherein the pattern is formed by etching a first resist pattern corresponding to the first oblique linear pattern and a second resist pattern corresponding to the second oblique linear pattern once.

10. A method of forming a pattern, comprising:
forming a plurality of linear patterns arranged in a parallel direction as a first parallel linear pattern;
forming a columnar pattern having an upper surface of an elliptical shape, as a first elliptical pattern, in an inter-pattern region interposed between two neighboring first parallel linear patterns and an inter-pattern region including two first parallel linear patterns adjacent to the inter-pattern region; and
processing the first parallel linear pattern such that the first parallel linear pattern is divided by an elliptical shape region in which the first elliptical pattern is formed, and each of the first parallel linear patterns is not divided in midstream in a region other than the elliptical shape region.

11. The method according to claim 10,
wherein when the elliptical pattern is formed,
a second elliptical pattern larger than the first elliptical pattern is formed in the inter-pattern region,
a slimming process amount on the second elliptical pattern is calculated based on a misalignment amount of the second elliptical pattern, and
the first elliptical pattern is formed by slimming the second elliptical pattern by the calculated slimming process amount.

12. The method according to claim 10,
wherein the columnar pattern is a pillar pattern.

13. The method according to claim 10,
wherein the columnar pattern is a hole pattern.

14. A method of manufacturing a semiconductor device, comprising:
forming a plurality of linear patterns arranged in a parallel direction as a first parallel linear pattern;
forming a linear pattern arranged above the first parallel linear pattern at a first oblique angle with respect to the first parallel linear pattern as a first oblique linear pattern;
forming a linear pattern that passes above a first overlap region which is one of regions in which the first parallel linear pattern overlaps the first oblique linear pattern and is arranged at a second oblique angle with respect to the first parallel linear pattern as a second oblique linear pattern;
forming a pattern using the first and second oblique linear patterns in a second overlap region in which the first oblique linear pattern overlaps the second oblique linear pattern;
forming a second parallel linear pattern using the pattern such that a plurality of second parallel linear patterns which are formed using the first parallel linear pattern and arranged in a parallel direction are divided by the second overlap region, and each of the second parallel linear patterns is not divided in midstream in a region other than the second overlap region; and
manufacturing a semiconductor device using the pattern,
wherein at least one of the first and second oblique angles is an angle other than a right angle.

15. The method according to claim 14,
wherein the first parallel linear pattern is formed using a sidewall process.

16. The method according to claim 15,
wherein when the first parallel linear pattern is formed, a connection pattern that connects two neighboring linear patterns among the first parallel linear patterns in a short direction is formed to include a part of a region in which the pattern is formed and a region at an outer side further than the region, and
the second parallel linear pattern is formed to be divided by a region in which the second overlap region and the connection pattern are formed.

17. The method according to claim 14,
wherein the first oblique angle or the second oblique angle is a right angle.

18. The method according to claim 14,
wherein each of the first and second parallel linear patterns is a group of a plurality of line patterns.

19. The method according to claim 14,
wherein each of the first and second parallel linear patterns is a group of a plurality of space patterns.

20. The method according to claim 14,
wherein at least one of the first and second oblique linear patterns is a plurality of line patterns.
